(19) United States
(12) Patent Application Publication
(10) Pub. No.: US 2026/0286188 A1
(43) Pub. Date: Sep. 24, 2026

(54) POLISHING COMPOSITION, METHOD FOR PRODUCING SUBSTRATE, AND POLISHING SYSTEM

(71) Applicant: FUJIMI INCORPORATED, Kiyosu-shi (JP)

(72) Inventor: Takahito Nagano, Tongluo Township (TW)

(73) Assignee: FUJIMI INCORPORATED, Kiyosu-shi (JP)

(21) Appl. No.: 19/569,627

(22) Filed: Mar. 17, 2026

(30) Foreign Application Priority Data
Mar. 19, 2025 (JP) 2025-044822
Aug. 12, 2025 (JP) 2025-134337

(51) Int. Cl. C09G 1/04; B24B 37/04

(52) U.S. Cl. CPC C09G 1/04; B24B 37/044

(57) ABSTRACT

The present disclosure provides a polishing composition excellent in the balance among an excellent unevenness elimination ability on an object to be polished, an enhancement in polishing removal rate of an object to be polished, and a defect reduction on a surface of a polished object.

The present disclosure relates to a polishing composition containing (A) an amine compound having a heterocyclic structure containing two or more nitrogen atoms, and (B) a water-soluble polymer, in which the content mass ratio of the component (A) to the component (B) (component (A)/component (B)) is 1 or more, the polishing composition has a pH of 8 or more, and the polishing composition is substantially free of an abrasive grain.

### TECHNICAL FIELD

The present disclosure relates to a polishing composition, a method for producing a substrate, and a polishing system.

### BACKGROUND ART

In general, very fine patterning technologies have been used for, for example, manufacturing of semiconductor devices, according to recent miniaturization and densification. Wires constituting semiconductor devices are, for example, multi-layered, thereby more complicating surface structures of semiconductor elements after stacking and also more increasing initial unevenness in surface films. Flatting technologies utilized for removal of initial unevenness in specified films formed on substrates are chemical mechanical polishing (CMP) processes. In a case where objects to be polished by CMP have silicon-containing materials, polishing compositions for such silicon-containing materials are applied.

For example, International Publication No. WO2016/143323 and International Publication No. WO2020/162144 each disclose a polishing composition to be used for polishing a silicon-containing material.

### SUMMARY OF INVENTION

For example, when a film containing a silicon-containing material having specified initial unevenness is polished to perform polishing of a portion corresponding to the height (thickness X (Å)) of such initial unevenness at a polishing removal rate V (Å/min), such unevenness is eliminated by polishing for X/V (min) as long as only an upper surface of a protruded portion of such unevenness is selectively polished. However, in practice, a bottom of a depressed portion is also progressively polished at a lower rate than that of the upper portion of the protruded portion of such unevenness, due to chemical etching in a CMP process, deflection of a polishing pad, or the like.

A polishing composition for a silicon-containing material is also demanded to have an unevenness elimination efficiency closer to 1 (allowing only an upper portion of a protruded portion to be more selectively polished), as an excellent polishing composition. The unevenness elimination efficiency is here determined as “(the amount (Å) of a portion corresponding to the height of unevenness eliminated by polishing in a certain polishing process (in one depressed portion, the height (Å) from the lowest portion of the depressed portion to the uppermost portion of a protruded portion constituting the depressed portion))/(the total amount of polishing in the polishing process (the distance (A) from the height of the uppermost portion of the protruded portion before polishing to the height of the uppermost portion of the protruded portion after polishing))”.

Meanwhile, the polishing composition disclosed in each of International Publication No. WO2016/143323 and International Publication No. WO2020/162144 was still insufficient in terms of polishing characteristics of an object to be polished containing a silicon-containing material (for example, material having a silicon-silicon bond), in particular, performance about the unevenness elimination efficiency, and there was room for improvement from this viewpoint. There are also demands for an enhancement in polishing removal rate of an object to be polished containing a silicon-containing material (for example, material having a silicon-silicon bond) and the reduction of defects (scratches, residues, and the like) on a polished object.

An object of the present disclosure is to provide a polishing composition excellent in the balance among an excellent unevenness elimination ability on an object to be polished, an enhancement in polishing removal rate of an object to be polished, and a defect reduction on a surface of a polished object.

The inventor of the present disclosure has made intensive studies in order to solve the above problems. As a result, the inventor has found that the above problems are solved by a polishing composition containing (A) an amine compound having a heterocyclic structure containing two or more nitrogen atoms, and (B) a water-soluble polymer, in which the content mass ratio of the component (A) to the component (B) (component (A)/component (B)) is 1 or more, the polishing composition has a pH of 8 or more, and the polishing composition is substantially free of an abrasive grain, thereby leading to completion of the present disclosure.

### DESCRIPTION OF EMBODIMENTS

The present disclosure relates to a polishing composition containing (A) an amine compound having a heterocyclic structure containing two or more nitrogen atoms, and (B) a water-soluble polymer, wherein the content mass ratio of the component (A) to the component (B) (component (A)/component (B)) is 1 or more, the polishing composition has a pH of 8 or more, and the polishing composition is substantially free of an abrasive grain. The polishing composition according to the present disclosure, which has such a configuration, is excellent in the balance among an excellent unevenness elimination ability on an object to be polished, an enhancement in polishing removal rate of an object to be polished, and a defect reduction on a surface of a polished object.

Hereinafter, embodiments of the present disclosure are described. The present disclosure is not limited only to the following embodiments.

Herein, operations, and measurement of physical properties and the like are performed under conditions of room temperature (20° C. or more and 25° C. or less) and a relative humidity of 40% RH or more and 50% RH or less, unless particularly noted.

Herein, “X or more and Y or less” is used to mean that numerical values (X and Y) described before and after this range are included as the lower limit value and the upper limit value. In a case where a plurality of descriptions “X or more and Y or less” is made, for example, in a case where “X1 or more and Y1 or less, or X2 or more and Y2 or less” is described, all of the disclosure where each numerical value is adopted as the upper limit, the disclosure where each numerical value is adopted as the lower limit, and the disclosure of any combination of such upper limit and lower limit are made (namely, these disclosures serve as legitimate bases for amendments). Specifically, all of respective amendments to X1 or more, Y2 or less, X1 or less, Y2 or more, X1 or more and X2 or less, and X1 or more and Y2 or less need to be deemed to be legitimate.

It is to be understood that all combinations of embodiments and descriptions disclosed herein are disclosed in the present application. In other words, it is to be understood that these combinations can serve as bases for amendments.

Herein, the “defect” is a collective term for any scratch and residue present on a surface of a polished object.

### [(A) Amine Compound Having Heterocyclic Structure Containing Two or More Nitrogen Atoms]

The polishing composition according to the present disclosure contains (A) an amine compound having a heterocyclic structure containing two or more nitrogen atoms (hereinafter, also simply referred to as “component (A)”). It is considered that an unshared electron pair on a nitrogen atom in the component (A) interacts with a chemical bond (in particular, silicon-silicon bond) of a material contained in an object to be polished to embrittle the chemical bond, and it is thus considered that the polishing removal rate of the object to be polished is enhanced.

The heterocyclic ring containing two or more nitrogen atoms in the component (A) may be an aromatic heterocyclic ring or an aliphatic heterocyclic ring. The heterocyclic ring may be a monocyclic structure or a polycyclic structure. In the case of the polycyclic structure, the cyclic structure may be a fused ring structure, a spiro ring structure, or a crosslinked ring structure.

Examples of the aromatic heterocyclic ring include a pyrazole ring, an imidazole ring, a 1,2,3-triazole ring, a 1,2,4-triazole ring, a tetrazole ring, a pyridazine ring, a pyrimidine ring, a pyrazine ring, a triazine ring (for example, 1,2,3-triazine ring, 1,2,4-triazine ring, and 1,3,5-triazine ring), a tetrazine ring (for example, 1,2,4,5-tetrazine ring), a quinoxaline ring, a quinazoline ring, a benzimidazole ring, and a naphthimidazole ring.

Examples of the aliphatic heterocyclic ring include a pyrazolidine ring, an imidazolidine ring, a 1,2,3-triazolidine ring, a 1,2,4-triazolidine ring, a pyrazoline ring, an imidazoline ring, a 1,2,3-triazoline ring, a 1,2,4-triazoline ring, a piperazine ring, a triazinane ring, a diazabicyclooctane ring, a diazabicyclononene ring, and a diazabicycloundecene ring.

The component (A) preferably contains at least one selected from the group consisting of a compound having an imidazole ring structure, a compound having an aliphatic polycyclic structure, and a compound having a piperazine ring structure.

### <Compound Having Imidazole Ring Structure>

Specific examples of the compound having an imidazole ring structure include imidazole, 2-methylimidazole, 2-ethylimidazole, 1-isobutyl-2-methylimidazole, 2-ethyl-4-methylimidazole, 2-phenylimidazole, 2-phenyl-4-methylimidazole, 1-benzyl-2-methylimidazole, 1-benzyl-2-phenylimidazole, and 1,2-dimethylimidazole.

### <Compound Having Aliphatic Polycyclic Structure>

Specific examples of the compound having an aliphatic polycyclic structure include 1,3-diazabicyclo[2,1,0]heptane, 1,4-diazabicyclo[2,1,0]heptane, 1,3-diazabicyclo[2,2,0]hexane, 1,3-diazabicyclo[2,1,1]hexane, 1,3-diazabicyclo[2,2,1]heptane, 1,4-diazabicyclo[2,2,1]heptane, 1,3-diazabicyclo[3,2,0]heptane, 1,4-diazabicyclo[3,2,0]heptane, 1,6-diazabicyclo[3,2,0]heptane, 1,3-diazabicyclo[2,2,2]octane, 1,4-diazabicyclo[2,2,2]octane (DABCO, triethylenediamine), 1,3-diazabicyclo[3,2,1]octane, 1,4-diazabicyclo[3,2,1]octane, 1,5-diazabicyclo[3,2,1]octane, 1,6-diazabicyclo[3,2,1]octane, 1,3-diazabicyclo[4,1,1]octane, 1,4-diazabicyclo[4,1,1]octane, 1,5-diazabicyclo[4,1,1]octane, 1,6-diazabicyclo[4,1,1]octane, 1,7-diazabicyclo[4,1,1]octane, 1,3-diazabicyclo[4,2,0]octane, 1,4-diazabicyclo[4,2,0]octane, 1,5-diazabicyclo[4,2,0]octane, 1,7-diazabicyclo[4,2,0]octane, 1,3-diazabicyclo[3,3,1]nonane, 1,4-diazabicyclo[3,3,1]nonane, 1,5-diazabicyclo[3,3,1]nonane, 1,3-diazabicyclo[3,2,2]nonane, 1,4-diazabicyclo[3,2,2]nonane, 1,5-diazabicyclo[3,2,2]nonane, 1,6-diazabicyclo[3,2,2]nonane, 1,8-diazabicyclo[3,2,2]nonane, 1,3-diazabicyclo[4,3,0]nonane, 1,4-diazabicyclo[4,3,0]nonane, 1,5-diazabicyclo[4,3,0]nonane, 1,6-diazabicyclo[4,3,0]nonane, 1,7-diazabicyclo[4,3,0]nonane, 1,8-diazabicyclo[4,3,0]nonane, 1,3-diazabicyclo[4,2,1]nonane, 1,4-diazabicyclo[4,2,1]nonane, 1,5-diazabicyclo[4,2,1]nonane, 1,6-diazabicyclo[4,2,1]nonane, 1,7-diazabicyclo[4,2,1]nonane, 1,3-diazabicyclo[5,2,0]nonane, 1,3-diazabicyclo[5,2,0]nonane, 1,4-diazabicyclo[5,2,0]nonane, 1,5-diazabicyclo[5,2,0]nonane, 1,6-diazabicyclo[5,2,0]nonane, 1,7-diazabicyclo[5,2,0]nonane, 1,8-diazabicyclo[5,2,0]nonane, 1,9-diazabicyclo[7,1,0]decane, 1,8-diazabicyclo[6,2,0]decane, 1,8-diazabicyclo[6,1,1]decane, 1,7-diazabicyclo[5,3,0]decane, 1,7-diazabicyclo[5,2,1]decane, 1,6-diazabicyclo[4,3,1]decane, 1,6-diazabicyclo[4,2,2]decane, 1,7-diazabicyclo[5,4,0]undecane, 1,7-diazabicyclo[5,3,1]undecane, 1,7-diazabicyclo[5,2,2]undecane, 1,7-diazabicyclo[4,4,1]undecane, 1,7-diazabicyclo[4,3,2]undecane, hexamethylenetetramine, 1,8-diazabicyclo[5,4,0]undec-7-ene (DBU), and 1,5-diazabicyclo[4,3,0]non-5-ene (DBN).

### <Compound Having Piperazine Ring Structure>

Examples of the compound having a piperazine ring structure include anhydrous piperazine, piperazine hexahydrate, 1-methylpiperazine, 2-methylpiperazine, 1-ethylpiperazine, 2-ethylpiperazine, 1-(n-propyl) piperazine, 2-(n-propyl) piperazine, 1-isopropylpiperazine, 1-allylpiperazine, 1-(n-butyl) piperazine, 1-isobutylpiperazine, 1-hydroxyethoxyethylpiperazine, 1-phenylpiperazine, 1-aminopiperazine, 1-amino-4-methylpiperazine, 1-(2-hydroxyethyl) piperazine, ethyl 1-piperazinecarboxylate, 1-formylpiperazine, 1-acetylpiperazine, 1-cyclopentylpiperazine, 1-cyclohexylpiperazine, 1-(2-methoxyethyl) piperazine, 1-piperonylpiperazine, 2-piperazinone, 1-methyl-3-1-(diphenylmethyl) piperazine, phenylpiperazine, 1,4-bis(3-aminopropyl) piperazine, 1-(2-dimethylaminoethyl)-4-methylpiperazine, 1-(2-aminoethyl) piperazine (AEP, aminoethylpiperazine), 1,4-bis(3-aminopropyl) piperazine (BAPP), 1,4-dimethylpiperazine, 2,5-dimethylpiperazine, 2,6-dimethylpiperazine, 1,4-diethylpiperazine, 1,4-dimethylpiperazin-2-one, 1,4-diethylpiperazin-2-one, 1,4-diformylpiperazine, 1-(4-aminophenyl)-4-methylpiperazine, 1,4-diacetyl-2,5-piperazinedione, 1-methyl-4-(1,4′-bipiperazin-4-yl) piperazine, 1-(4-aminophenyl)-4-(4-methoxyphenyl) piperazine, 1,4-dimethylpiperazin-2,3-dione, and 2-piperazinecarboxylic acid.

Such components (A) may be used singly or in combinations of two or more kinds thereof. The component (A) used here may be a synthetic product or a commercially available product.

The component (A) preferably includes at least one selected from the group consisting of anhydrous piperazine, piperazine hexahydrate, imidazole, 1,4-diazabicyclo[2,2,0]octane (DABCO), 1,4-bis(3-aminopropyl) piperazine, and 1-(2-aminoethyl) piperazine, more preferably includes at least one selected from the group consisting of imidazole, 1,4-diazabicyclo[2,2,0]octane (DABCO), 1,4-bis(3-aminopropyl) piperazine, and 1-(2-aminoethyl) piperazine, further preferably includes 1-(2-aminoethyl) piperazine.

The concentration (content) of the component (A) in the polishing composition is not particularly limited, and the concentration under the assumption that the total mass of the polishing composition is 100% by mass is preferably 0.01% by mass or more, and can be 0.015% by mass or more, 0.02% by mass or more, 0.025% by mass or more, 0.03% by mass or more, 0.035% by mass or more, 0.04% by mass or more, 0.045% by mass or more, 0.05% by mass or more, 0.055% by mass or more, 0.06% by mass or more, 0.065% by mass or more, 0.07% by mass or more, 0.075% by mass or more, 0.08% by mass or more, 0.085% by mass or more, 0.09% by mass or more, 0.095% by mass or more, 0.1% by mass or more, 0.15% by mass or more, 0.2% by mass or more, 0.25% by mass or more, 0.3% by mass or more, 0.35% by mass or more, 0.4% by mass or more, 0.45% by mass or more, 0.5% by mass or more, more than 0.5% by mass, 0.55% by mass or more, 0.6% by mass or more, 0.65% by mass or more, 0.7% by mass or more, 0.75% by mass or more, 0.8% by mass or more, 0.85% by mass or more, 0.9% by mass or more, 0.95% by mass or more, 1.0% by mass or more, 1.1% by mass or more, 1.2% by mass or more, 1.3% by mass or more, 1.4% by mass or more, 1.5% by mass or more, 1.6% by mass or more, 1.7% by mass or more, 1.8% by mass or more, 1.9% by mass or more, 2.0% by mass or more, 2.1% by mass or more, 2.2% by mass or more, 2.3% by mass or more, 2.4% by mass or more, 2.5% by mass or more, 2.6% by mass or more, 2.7% by mass or more, 2.8% by mass or more, 2.9% by mass or more, 3.0% by mass or more, 3.1% by mass or more, 3.2% by mass or more, 3.3% by mass or more, 3.4% by mass or more, 3.5% by mass or more, 3.6% by mass or more, 3.7% by mass or more, 3.8% by mass or more, 3.9% by mass or more, 4.0% by mass or more, 4.1% by mass or more, 4.2% by mass or more, 4.3% by mass or more, 4.4% by mass or more, 4.5% by mass or more, 4.6% by mass or more, 4.7% by mass or more, 4.8% by mass or more, 4.9% by mass or more, 5.0% by mass or more, 5.1% by mass or more, 5.2% by mass or more, 5.3% by mass or more, 5.4% by mass or more, 5.5% by mass or more, 5.6% by mass or more, 5.7% by mass or more, 5.8% by mass or more, 5.9% by mass or more, 6.0% by mass or more, 6.1% by mass or more, 6.2% by mass or more, 6.3% by mass or more, 6.4% by mass or more, 6.5% by mass or more, 6.6% by mass or more, 6.7% by mass or more, 6.8% by mass or more, 6.9% by mass or more, 7.0% by mass or more, 7.1% by mass or more, 7.2% by mass or more, 7.3% by mass or more, 7.4% by mass or more, 7.5% by mass or more, 7.6% by mass or more, 7.7% by mass or more, 7.8% by mass or more, 7.9% by mass or more, 8.0% by mass or more, 8.1% by mass or more, 8.2% by mass or more, 8.3% by mass or more, 8.4% by mass or more, 8.5% by mass or more, 8.6% by mass or more, 8.7% by mass or more, 8.8% by mass or more, 8.9% by mass or more, 9.0% by mass or more, 9.1% by mass or more, 9.2% by mass or more, 9.3% by mass or more, 9.4% by mass or more, 9.5% by mass or more, 9.6% by mass or more, 9.7% by mass or more, 9.8% by mass or more, or 9.9% by mass or more.

The concentration (content) of the component (A) in the polishing composition is not particularly limited, and the concentration under the assumption that the total mass of the polishing composition is 100% by mass is preferably 20.0% by mass or less, and can be 10.0% by mass or less, 9.9% by mass or less, 9.8% by mass or less, 9.7% by mass or less, 9.6% by mass or less, 9.5% by mass or less, 9.4% by mass or less, 9.3% by mass or less, 9.2% by mass or less, 9.1% by mass or less, 9.0% by mass or less, 8.9% by mass or less, 8.8% by mass or less, 8.7% by mass or less, 8.6% by mass or less, 8.5% by mass or less, 8.4% by mass or less, 8.3% by mass or less, 8.2% by mass or less, 8.1% by mass or less, 8.0% by mass or less, 7.9% by mass or less, 7.8% by mass or less, 7.7% by mass or less, 7.6% by mass or less, 7.5% by mass or less, 7.4% by mass or less, 7.3% by mass or less, 7.2% by mass or less, 7.1% by mass or less, 7.0% by mass or less, 6.9% by mass or less, 6.8% by mass or less, 6.7% by mass or less, 6.6% by mass or less, 6.5% by mass or less, 6.4% by mass or less, 6.3% by mass or less, 6.2% by mass or less, 6.1% by mass or less, 6.0% by mass or less, 5.9% by mass or less, 5.8% by mass or less, 5.7% by mass or less, 5.6% by mass or less, 5.5% by mass or less, 5.4% by mass or less, 5.3% by mass or less, 5.2% by mass or less, 5.1% by mass or less, 5.0% by mass or less, 4.9% by mass or less, 4.8% by mass or less, 4.7% by mass or less, 4.6% by mass or less, 4.5% by mass or less, 4.4% by mass or less, 4.3% by mass or less, 4.2% by mass or less, 4.1% by mass or less, 4.0% by mass or less, 3.9% by mass or less, 3.8% by mass or less, 3.7% by mass or less, 3.6% by mass or less, 3.5% by mass or less, 3.4% by mass or less, 3.3% by mass or less, 3.2% by mass or less, 3.1% by mass or less, 3.0% by mass or less, 2.9% by mass or less, 2.8% by mass or less, 2.7% by mass or less, 2.6% by mass or less, 2.5% by mass or less, 2.4% by mass or less, 2.3% by mass or less, 2.2% by mass or less, 2.1% by mass or less, 2.0% by mass or less, 1.9% by mass or less, 1.8% by mass or less, 1.7% by mass or less, 1.6% by mass or less, 1.5% by mass or less, 1.4% by mass or less, 1.3% by mass or less, 1.2% by mass or less, 1.1% by mass or less, 1.0% by mass or less, less than 1.0% by mass, 0.95% by mass or less, 0.9% by mass or less, 0.85% by mass or less, 0.8% by mass or less, 0.75% by mass or less, 0.7% by mass or less, 0.65% by mass or less, 0.6% by mass or less, 0.55% by mass or less, 0.5% by mass or less, 0.45% by mass or less, 0.4% by mass or less, 0.35% by mass or less, 0.3% by mass or less, 0.25% by mass or less, 0.2% by mass or less, 0.15% by mass or less, 0.1% by mass or less, 0.095% by mass or less, 0.09% by mass or less, 0.085% by mass or less, 0.08% by mass or less, 0.075% by mass or less, 0.07% by mass or less, 0.065% by mass or less, 0.06% by mass or less, 0.055% by mass or less, 0.05% by mass or less, 0.045% by mass or less, 0.04% by mass or less, 0.035% by mass or less, 0.03% by mass or less, 0.025% by mass or less, 0.02% by mass or less, or 0.015% by mass or less. When the concentration (content) of the component (A) is 20.0% by mass or less, the number of defects can be reduced and the surface roughness of an object to be polished can be decreased.

When the concentration (content) of the component (A) falls within the above range, the polishing removal rate of an object to be polished is more enhanced. In a case where the polishing composition contains two or more such components (A), the concentration (content) of the component (A) means the total amount of such components (A).

The concentration (content) of the component (A) in the polishing composition, under the assumption that the total mass of the polishing composition is 100% by mass, is preferably 0.5% by mass or more, and is sequentially more preferably more than 0.5% by mass, 0.8% by mass or more, 1.0% by mass or more, 2.0% by mass or more, 3.0% by mass or more, or 3.5% by mass or more, from the viewpoint of a further enhancement in polishing removal rate of an object to be polished. The concentration (content) of the component (A) in the polishing composition, under the assumption that the total mass of the polishing composition is 100% by mass, is preferably 10.0% by mass or less, and is sequentially more preferably 8.0% by mass or less, 7.0% by mass or less, 6.0% by mass or less, 5.5% by mass or less, or 5.0% by mass or less, from the same viewpoint. The concentration (content) of the component (A) in the polishing composition, under the assumption that the total mass of the polishing composition is 100% by mass, is preferably 0.5% by mass or more and 10.0% by mass or less, and is sequentially more preferably more than 0.5% by mass and 10.0% by mass or less, 0.8% by mass or more and 8.0% by mass or less, 1.0% by mass or more and 7.0% by mass or less, 1.0% by mass or more and 6.0% by mass or less, 2.0% by mass or more and 6.0% by mass or less, 2.0% by mass or more and 5.5% by mass or less, or 3.0% by mass or more and 5.0% by mass or less, from the viewpoint of a further enhancement in polishing removal rate of an object to be polished.

The concentration (content) of the component (A) in the polishing composition, under the assumption that the total mass of the polishing composition is 100% by mass, is preferably 0.01% by mass or more, and is sequentially more preferably 0.05% by mass or more, 0.1% by mass or more, 0.2% by mass or more, 0.3% by mass or more, or 0.4% by mass or more, from the viewpoint of a more enhancement in the balance among an excellent unevenness elimination ability on an object to be polished, an enhancement in polishing removal rate of an object to be polished, and a defect reduction on a surface of a polished object. The concentration (content) of the component (A) in the polishing composition, under the assumption that the total mass of the polishing composition is 100% by mass, is preferably 2.0% by mass or less, and is sequentially more preferably 1.5% by mass or less, 1.0% by mass or less, 0.8% by mass or less, 0.7% by mass or less, or 0.6% by mass or less, from the same viewpoint. The concentration (content) of the component (A) in the polishing composition, under the assumption that the total mass of the polishing composition is 100% by mass, is preferably 0.01% by mass or more and 2.0% by mass or less, and is sequentially more preferably 0.05% by mass or more and 2.0% by mass or less, 0.05% by mass or more and 1.5% by mass or less, 0.05% by mass or more and 1.0% by mass or less, 0.1% by mass or more and 1.0% by mass or less, 0.1% by mass or more and 0.8% by mass or less, 0.2% by mass or more and 0.8% by mass or less, 0.3% by mass or more and 0.7% by mass or less, 0.4% by mass or more and 0.6% by mass or less, from the viewpoint of a more enhancement in the balance among an excellent unevenness elimination ability on an object to be polished, an enhancement in polishing removal rate of an object to be polished, and a defect reduction on a surface of a polished object.

### [(B) Water-Soluble Polymer]

The polishing composition according to the present disclosure contains (B) a water-soluble polymer (hereinafter, also simply referred to as “component (B)”). Although the action mechanism is not limited to the following, the component (B) adsorbs to a surface of an object to be polished by hydrogen bonding or hydrophobic interaction, thereby forming a protective film. While this formation of the protective film occurs competitively with peeling of the protective film by polishing, the protective film is hardly peeled on a depressed portion as compared with a protruded portion and therefore it is considered that the polishing removal rate of the depressed portion is kept lower than the polishing removal rate of the protruded portion and the unevenness elimination ability is enhanced. In other words, it is considered that the component (B) functions as an additive for unevenness elimination. The component (B) can also have the function of reduction of defects on a surface of a polished object.

The type of the water-soluble polymer is not particularly limited, and any of a cationic water-soluble polymer, an anionic water-soluble polymer, a non-ionic water-soluble polymer, and an amphoteric water-soluble polymer can be used. In particular, the component (B) preferably includes a non-ionic water-soluble polymer.

The non-ionic water-soluble polymer can be a compound which is a polymer having the same (homopolymer) or different (copolymer) repeating constituent units and which typically has a weight average molecular weight (Mw) of 1,000 or more. In a case where the non-ionic water-soluble polymer is a copolymer, the form of the copolymer may be any of a block copolymer, a random copolymer, a graft copolymer, and an alternate copolymer.

Examples of the non-ionic water-soluble polymer include polyvinyl alcohol (PVA), polyvinylpyrrolidone (PVP), polyacrylamide, poly-N-vinylacetamide, polyvinyl ethers (polyvinyl methyl ether, polyvinyl ethyl ether, polyvinyl isobutyl ether, and the like), polyglycerin, polyethylene glycol, polypropylene glycol, water-soluble polysaccharides such as hydroxyethylcellulose, alginic acid polyhydric alcohol ester, a water-soluble urea resin, a dextrin derivative, and casein. Not only one having such a main structure, but also a graft copolymer having a non-ionic polymer structure at a side chain can also be suitably used. Furthermore, a copolymer such as an ethylene-vinyl alcohol copolymer or a butenediol-vinyl alcohol copolymer can also be used. Such non-ionic water-soluble polymers may be used singly or in combinations of two or more kinds thereof. The non-ionic water-soluble polymer used here may be a synthetic product or a commercially available product.

Suitable examples of the non-ionic water-soluble polymer include polyvinyl alcohol, polyvinylpyrrolidone, polyacrylamide, poly-N-vinylacetamide, polyethylene glycol, hydroxyethylcellulose, and a butenediol-vinyl alcohol copolymer from the viewpoint of further enhancements of the effects of the present disclosure. Therefore, in one preferred embodiment of the present disclosure, the non-ionic water-soluble polymer preferably includes at least one selected from the group consisting of polyvinyl alcohol, polyvinylpyrrolidone, polyacrylamide, poly-N-vinylacetamide, polyethylene glycol, hydroxyethylcellulose and a butenediol-vinyl alcohol copolymer. Furthermore, in another embodiment of the present disclosure, the non-ionic water-soluble polymer preferably includes at least one selected from the group consisting of polyvinyl alcohol, polyvinylpyrrolidone and poly-N-vinylacetamide. In still another embodiment, the non-ionic water-soluble polymer preferably includes polyvinyl alcohol or polyvinylpyrrolidone. In one further preferred embodiment of the present disclosure, the non-ionic water-soluble polymer preferably includes polyvinylpyrrolidone.

The lower limit of the weight average molecular weight (Mw) of the component (B) is not particularly limited, and is preferably 1,000 or more, more preferably 3,000 or more, further preferably more than 5,000, particularly preferably 8,000 or more, still further preferably 10,000 or more, may be, for example, 20,000 or more, and is most preferably 30,000 or more. The upper limit of the weight average molecular weight (Mw) of the component (B) is not particularly limited, and is preferably 1,000,000 or less, more preferably 400,000 or less, further preferably 300,000 or less, still further preferably 200,000 or less, still further preferably 100,000 or less, particularly preferably 80,000 or less, may be, for example, 50,000 or less, and is most preferably less than 50,000. In other words, the weight average molecular weight (Mw) of the component (B) is preferably 1,000 or more and 1,000,000 or less, and can be 3,000 or more and 400,000 or less, more than 5,000 and 300,000 or less, 10,000 or more and 300,000 or less, 20,000 or more and 300,000 or less, 30,000 or more and 300,000 or less, 10,000 or more and 200,000 or less, 20,000 or more and 200,000 or less, 30,000 or more and 200,000 or less, 10,000 or more and 100,000 or less, 20,000 or more and 100,000 or less, 30,000 or more and 100,000 or less, more than 5,000 and 80,000 or less, more than 5,000 and 50,000 or less, 8,000 or more and 80,000 or less, 8,000 or more and 50,000 or less, 10,000 or more and 50,000 or less, 20,000 or more and 50,000 or less, 30,000 or more and 50,000 or less, 10,000 or more and less than 50,000, 20,000 or more and less than 50,000, or 30,000 or more and less than 50,000.

The weight average molecular weight (Mw) of the component (B) (water-soluble polymer) can be measured as a value in terms of polyethylene glycol with gel permeation chromatography (GPC). The detail of the measurement method is described in Examples below.

The component (B) may be used singly or in combinations of two or more kinds thereof. The component (B) used here may be a synthetic product or a commercially available product.

The concentration (content) of the component (B) in the polishing composition is not particularly limited, and the concentration under the assumption that the total mass of the polishing composition is 100% by mass is preferably 0.001% by mass or more, and can be 0.0012% by mass or more, 0.0015% by mass or more, 0.0017% by mass or more, 0.002% by mass or more, 0.0022% by mass or more, 0.0025% by mass or more, 0.0027% by mass or more, 0.003% by mass or more, 0.0032% by mass or more, 0.0035% by mass or more, 0.0037% by mass or more, 0.004% by mass or more, 0.0042% by mass or more, 0.0045% by mass or more, 0.0047% by mass or more, 0.005% by mass or more, 0.0052% by mass or more, 0.0055% by mass or more, 0.0057% by mass or more, 0.006% by mass or more, 0.0062% by mass or more, 0.0065% by mass or more, 0.0067% by mass or more, 0.007% by mass or more, 0.0072% by mass or more, 0.0075% by mass or more, 0.0077% by mass or more, 0.008% by mass or more, 0.0082% by mass or more, 0.0085% by mass or more, 0.0087% by mass or more, 0.009% by mass or more, 0.0092% by mass or more, 0.0095% by mass or more, 0.0097% by mass or more, 0.01% by mass or more, 0.012% by mass or more, 0.015% by mass or more, 0.017% by mass or more, 0.02% by mass or more, 0.022% by mass or more, 0.025% by mass or more, 0.027% by mass or more, 0.03% by mass or more, 0.032% by mass or more, 0.035% by mass or more, 0.037% by mass or more, 0.04% by mass or more, 0.042% by mass or more, 0.045% by mass or more, 0.047% by mass or more, 0.05% by mass or more, 0.052% by mass or more, 0.055% by mass or more, 0.057% by mass or more, 0.06% by mass or more, 0.062% by mass or more, 0.065% by mass or more, 0.067% by mass or more, 0.07% by mass or more, 0.072% by mass or more, 0.075% by mass or more, 0.077% by mass or more, 0.08% by mass or more, 0.082% by mass or more, 0.085% by mass or more, 0.087% by mass or more, 0.09% by mass or more, 0.092% by mass or more, 0.095% by mass or more, 0.097% by mass or more, 0.1% by mass or more, 0.15% by mass or more, 0.2% by mass or more, 0.3% by mass or more, 0.35% by mass or more, 0.4% by mass or more, 0.45% by mass or more, 0.5% by mass or more, 0.55% by mass or more, 0.6% by mass or more, 0.65% by mass or more, 0.7% by mass or more, 0.75% by mass or more, 0.08% by mass or more, 0.85% by mass or more, 0.9% by mass or more, 0.95% by mass or more, 1.0% by mass or more, 1.2% by mass or more, 1.4% by mass or more, 1.6% by mass or more, 1.8% by mass or more, 2.0% by mass or more, 2.2% by mass or more, 2.4% by mass or more, 2.6% by mass or more, 2.8% by mass or more, 3.0% by mass or more, 3.2% by mass or more, 3.4% by mass or more, 3.6% by mass or more, 3.8% by mass or more, 4.0% by mass or more, 4.2% by mass or more, 4.4% by mass or more, 4.6% by mass or more, 4.8% by mass or more, 5.0% by mass or more, 5.2% by mass or more, 5.4% by mass or more, 5.6% by mass or more, 5.8% by mass or more, 6.0% by mass or more, 6.2% by mass or more, 6.4% by mass or more, 6.6% by mass or more, 6.8% by mass or more, 7.0% by mass or more, 7.2% by mass or more, 7.4% by mass or more, 7.6% by mass or more, 7.8% by mass or more, 8.0% by mass or more, 8.2% by mass or more, 8.4% by mass or more, 8.6% by mass or more, 8.8% by mass or more, 9.0% by mass or more, 9.2% by mass or more, 9.4% by mass or more, 9.6% by mass or more, or 9.8% by mass or more.

The concentration (content) of the component (B) in the polishing composition is not particularly limited, and the concentration under the assumption that the total mass of the polishing composition is 100% by mass is preferably 20% by mass or less, and can be 10.0% by mass or less, 9.8% by mass or less, 9.6% by mass or less, 9.4% by mass or less, 9.2% by mass or less, 9.0% by mass or less, 8.8% by mass or less, 8.6% by mass or less, 8.4% by mass or less, 8.2% by mass or less, 8.0% by mass or less, 7.8% by mass or less, 7.6% by mass or less, 7.4% by mass or less, 7.2% by mass or less, 7.0% by mass or less, 6.8% by mass or less, 6.6% by mass or less, 6.4% by mass or less, 6.2% by mass or less, 6.0% by mass or less, 5.8% by mass or less, 5.6% by mass or less, 5.4% by mass or less, 5.2% by mass or less, 5.0% by mass or less, 4.8% by mass or less, 4.6% by mass or less, 4.4% by mass or less, 4.2% by mass or less, 4.0% by mass or less, 3.8% by mass or less, 3.6% by mass or less, 3.4% by mass or less, 3.2% by mass or less, 3.0% by mass or less, 2.8% by mass or less, 2.6% by mass or less, 2.4% by mass or less, 2.2% by mass or less, 2.0% by mass or less, 1.8% by mass or less, 1.6% by mass or less, 1.4% by mass or less, 1.2% by mass or less, 1.0% by mass or less, 0.95% by mass or less, 0.9% by mass or less, 0.85% by mass or less, 0.8% by mass or less, 0.75% by mass or less, 0.7% by mass or less, 0.65% by mass or less, 0.6% by mass or less, 0.55% by mass or less, 0.5% by mass or less, 0.45% by mass or less, 0.4% by mass or less, 0.35% by mass or less, 0.3% by mass or less, 0.25% by mass or less, 0.2% by mass or less, 0.15% by mass or less, 0.1% by mass or less, 0.097% by mass or less, 0.095% by mass or less, 0.092% by mass or less, 0.09% by mass or less, 0.087% by mass or less, 0.085% by mass or less, 0.082% by mass or less, 0.08% by mass or less, 0.077% by mass or less, 0.075% by mass or less, 0.072% by mass or less, 0.07% by mass or less, 0.067% by mass or less, 0.065% by mass or less, 0.062% by mass or less, 0.06% by mass or less, 0.057% by mass or less, 0.055% by mass or less, 0.052% by mass or less, 0.05% by mass or less, 0.047% by mass or less, 0.045% by mass or less, 0.042% by mass or less, 0.04% by mass or less, 0.037% by mass or less, 0.035% by mass or less, 0.032% by mass or less, 0.03% by mass or less, 0.027% by mass or less, 0.025% by mass or less, 0.022% by mass or less, 0.02% by mass or less, 0.017% by mass or less, 0.015% by mass or less, 0.012% by mass or less, 0.01% by mass or less, 0.0097% by mass or less, 0.0095% by mass or less, 0.0092% by mass or less, 0.009% by mass or less, 0.0087% by mass or less, 0.0085% by mass or less, 0.0082% by mass or less, 0.008% by mass or less, 0.0077% by mass or less, 0.0075% by mass or less, 0.0072% by mass or less, 0.007% by mass or less, 0.0067% by mass or less, 0.0065% by mass or less, 0.0062% by mass or less, 0.006% by mass or less, 0.0057% by mass or less, 0.0055% by mass or less, 0.0052% by mass or less, 0.005% by mass or less, 0.0047% by mass or less, 0.0045% by mass or less, 0.0042% by mass or less, 0.004% by mass or less, 0.0037% by mass or less, 0.0035% by mass or less, 0.0032% by mass or less, 0.003% by mass or less, 0.0027% by mass or less, 0.0025% by mass or less, 0.0022% by mass or less, 0.002% by mass or less, 0.0017% by mass or less, 0.0015% by mass or less, or 0.0012% by mass or less.

The concentration (content) of the component (B) in the polishing composition, under the assumption that the total mass of the polishing composition is 100% by mass, is preferably 0.0025% by mass or more, and is sequentially more preferably 0.005% by mass or more, 0.007% by mass or more, 0.0075% by mass or more, 0.01% by mass or more, 0.012% by mass or more, or 0.015% by mass or more, from the viewpoint of a further enhancement in polishing removal rate of an object to be polished. The concentration (content) of the component (B) in the polishing composition, under the assumption that the total mass of the polishing composition is 100% by mass, is preferably 1.0% by mass or less, and is sequentially more preferably 0.5% by mass or less, 0.3% by mass or less, 0.2% by mass or less, 0.1% by mass or less, or 0.05% by mass or less, from the same viewpoint. The concentration (content) of the component (B) in the polishing composition, under the assumption that the total mass of the polishing composition is 100% by mass, is preferably 0.0025% by mass or more and 1.0% by mass or less, or may be 0.005% by mass or more and 0.5% by mass or less, 0.007% by mass or more and 0.3% by mass or less, 0.0075% by mass or more and 0.2% by mass or less, 0.01% by mass or more and 0.2% by mass or less, 0.01% by mass or more and 0.1% by mass or less, 0.01% by mass or more and 0.05% by mass or less, or 0.015% by mass or more and 0.05% by mass or less, from the viewpoint of a further enhancement in polishing removal rate of an object to be polished.

The concentration (content) of the component (B) in the polishing composition, under the assumption that the total mass of the polishing composition is 100% by mass, is preferably 0.0025% by mass or more, and is sequentially more preferably 0.005% by mass or more, 0.007% by mass or more, 0.0075% by mass or more, 0.01% by mass or more, 0.012% by mass or more, or 0.015% by mass or more, from the viewpoint of a more enhancement in the balance among an excellent unevenness elimination ability on an object to be polished, an enhancement in polishing removal rate of an object to be polished, and a defect reduction on a surface of a polished object. The concentration (content) of the component (B) in the polishing composition, under the assumption that the total mass of the polishing composition is 100% by mass, is preferably 1.0% by mass or less, and is sequentially more preferably 0.5% by mass or less, 0.3% by mass or less, 0.2% by mass or less, 0.1% by mass or less, or 0.05% by mass or less, from the same viewpoint. The concentration (content) of the component (B) in the polishing composition, under the assumption that the total mass of the polishing composition is 100% by mass, is preferably 0.0025% by mass or more and 1.0% by mass or less, or may be 0.005% by mass or more and 0.5% by mass or less, 0.007% by mass or more and 0.3% by mass or less, 0.0075% by mass or more and 0.2% by mass or less, 0.01% by mass or more and 0.2% by mass or less, 0.01% by mass or more and 0.1% by mass or less, 0.01% by mass or more and 0.05% by mass or less, or 0.015% by mass or more and 0.05% by mass or less, from the viewpoint of a more enhancement in the balance among an excellent unevenness elimination ability on an object to be polished, an enhancement in polishing removal rate of an object to be polished, and a defect reduction on a surface of a polished object.

When the concentration (content) of the component (B) falls within the above range, a polishing composition which is more excellent in unevenness elimination ability and which can more reduce defects on a surface of a polished object can be obtained. In a case where the polishing composition contains two or more such components (B), the concentration (content) of the component (B) means the total amount of such components (B).

### [Content Mass Ratio of Component (A) and Component (B)]

The content mass ratio of the component (A) to the component (B) (component (A)/component (B)) in the polishing composition according to the present disclosure is 1 or more. If the content mass ratio is less than 1, the polishing removal rate of an object to be polished is lowered.

The content mass ratio of the component (A) to the component (B) (component (A)/component (B)) is preferably 1.1 or more, and can be 1.2 or more, 1.5 or more, 1.7 or more, 2.0 or more, 2.2 or more, 2.5 or more, 2.7 or more, 3.0 or more, 3.2 or more, 3.5 or more, 3.7 or more, 4.0 or more, 4.2 or more, 4.5 or more, 4.7 or more, 5.0 or more, 5.2 or more, 5.5 or more, 5.7 or more, 6.0 or more, 6.2 or more, 6.5 or more, 6.7 or more, 7.0 or more, 7.5 or more, 7.7 or more, 8.0 or more, 8.2 or more, 8.5 or more, 8.7 or more, 9.0 or more, 9.2 or more, 9.5 or more, 9.7 or more, 10.0 or more, more than 10.0, 10.2 or more, 10.5 or more, 10.7 or more, 11.0 or more, 11.2 or more, 11.5 or more, 11.7 or more, 12.0 or more, 12.2 or more, 12.5 or more, 12.7 or more, 13.0 or more, 13.2 or more, 13.5 or more, 13.7 or more, 14.0 or more, 14.2 or more, 14.5 or more, 14.7 or more, 15.0 or more, 15.5 or more, 16.0 or more, 16.5 or more, 17.0 or more, 17.5 or more, 18.0 or more, 18.2 or more, 18.5 or more, 18.7 or more, 19.0 or more, 19.2 or more, 19.5 or more, 19.7 or more, 20.0 or more, 21.0 or more, 22.0 or more, 23.0 or more, 24.0 or more, 25.0 or more, 26.0 or more, 27.0 or more, 28.0 or more, 29.0 or more, 30.0 or more, 31.0 or more, 32.0 or more, 33.0 or more, 34.0 or more, 35.0 or more, 36.0 or more, 37.0 or more, 38.0 or more, 39.0 or more, 40.0 or more, 41.0 or more, 42.0 or more, 43.0 or more, 44.0 or more, 45.0 or more, 46.0 or more, 47.0 or more, 48.0 or more, 49.0 or more, 50.0 or more, 53.0 or more, 55.0 or more, 57.0 or more, 60.0 or more, 63.0 or more, 65.0 or more, 67.0 or more, 70.0 or more, 73.0 or more, 75.0 or more, 77.0 or more, 80.0 or more, 83.0 or more, 85.0 or more, 87.0 or more, 90.0 or more, 93.0 or more, 95.0 or more, 97.0 or more, 100.0 or more, 105.0 or more, 110.0 or more, 115.0 or more, 120.0 or more, 125.0 or more, 130.0 or more, 135.0 or more, 140.0 or more, 145.0 or more, 150.0 or more, 155.0 or more, 160.0 or more, 165.0 or more, 170.0 or more, 175.0 or more, 180.0 or more, 185.0 or more, 190.0 or more, 195.0 or more, 200.0 or more, 205.0 or more, 210.0 or more, 215.0 or more, 220.0 or more, 225.0 or more, 230.0 or more, 235.0 or more, 240.0 or more, 245.0 or more, 250.0 or more, 255.0 or more, 260.0 or more, 265.0 or more, 270.0 or more, 275.0 or more, 280.0 or more, 285.0 or more, 290.0 or more, 295.0 or more, 300.0 or more, 305.0 or more, 310.0 or more, 315.0 or more, 320.0 or more, 325.0 or more, 330.0 or more, 335.0 or more, 340.0 or more, 345.0 or more, 350.0 or more, 355.0 or more, 360.0 or more, 365.0 or more, 370.0 or more, 375.0 or more, 380.0 or more, 385.0 or more, 390.0 or more, 395.0 or more, 400.0 or more, 405.0 or more, 410.0 or more, 415.0 or more, 420.0 or more, 425.0 or more, 430.0 or more, 435.0 or more, 440.0 or more, 445.0 or more, 450.0 or more, 455.0 or more, 460.0 or more, 465.0 or more, 470.0 or more, 475.0 or more, 480.0 or more, 485.0 or more, 490.0 or more, or 495.0 or more.

The content mass ratio of the component (A) to the component (B) (component (A)/component (B)) is preferably 500.0 or less, and can be 495.0 or less, 490.0 or less, 485.0 or less, 480.0 or less, 475.0 or less, 470.0 or less, 465.0 or less, 460.0 or less, 455.5 or less, 450.0 or less, 445.5 or less, 440.0 or less, 435.0 or less, 430.0 or less, 425.0 or less, 420.0 or less, 415.0 or less, 410.0 or less, 405.0 or less, 400.0 or less, 395.0 or less, 390.0 or less, 385.0 or less, 380.0 or less, 375.0 or less, 370.0 or less, 365.0 or less, 360.0 or less, 355.5 or less, 350.0 or less, 345.5 or less, 340.0 or less, 335.0 or less, 330.0 or less, 325.0 or less, 320.0 or less, 315.0 or less, 310.0 or less, 305.0 or less, 300.0 or less, 295.0 or less, 290.0 or less, 285.0 or less, 280.0 or less, 275.0 or less, 270.0 or less, 265.0 or less, 260.0 or less, 255.5 or less, 250.0 or less, 245.5 or less, 240.0 or less, 235.0 or less, 230.0 or less, 225.0 or less, 220.0 or less, 215.0 or less, 210.0 or less, 205.0 or less, 200.0 or less, 195.0 or less, 190.0 or less, 185.0 or less, 180.0 or less, 175.0 or less, 170.0 or less, 165.0 or less, 160.0 or less, 155.5 or less, 150.0 or less, 145.5 or less, 140.0 or less, 135.0 or less, 130.0 or less, 125.0 or less, 120.0 or less, 115.0 or less, 110.0 or less, 105.0 or less, 100.0 or less, 97.0 or less, 95.0 or less, 93.0 or less, 90.0 or less, 87.0 or less, 85.0 or less, 83.0 or less, 80.0 or less, 77.0 or less, 75.0 or less, 73.0 or less, 70.0 or less, 67.0 or less, 65.0 or less, 63.0 or less, 60.0 or less, 57.0 or less, 55.0 or less, 53.0 or less, 50.0 or less, 49.0 or less, 48.0 or less, 47.0 or less, 46.0 or less, 45.0 or less, 44.0 or less, 43.0 or less, 42.0 or less, 41.0 or less, 40.0 or less, 39.0 or less, 38.0 or less, 37.0 or less, 36.0 or less, 35.0 or less, 34.0 or less, 33.0 or less, 32.0 or less, 31.0 or less, 30.0 or less, 29.0 or less, 28.0 or less, 27.0 or less, 26.0 or less, 25.0 or less, 24.0 or less, 23.0 or less, 22.0 or less, 21.0 or less, 20.0 or less, 19.7 or less, 19.5 or less, 19.2 or less, 19.0 or less, 18.7 or less, 18.5 or less, 18.2 or less, 18.0 or less, 17.7 or less, 17.5 or less, 17.2 or less, 17.0 or less, 16.7 or less, 16.5 or less, 16.2 or less, 16.0 or less, 15.7 or less, 15.5 or less, 15.2 or less, 15.0 or less, 14.7 or less, 14.5 or less, 14.2 or less, 14.0 or less, 13.7 or less, 13.5 or less, 13.2 or less, 13.0 or less, 12.7 or less, 12.5 or less, 12.2 or less, 12.0 or less, 12.7 or less, 12.5 or less, 12.2 or less, 12.0 or less, 11.7 or less, 11.5 or less, 11.2 or less, 11.0 or less, 9.7 or less, 9.5 or less, 9.2 or less, 9.0 or less, 8.7 or less, 8.5 or less, 8.2 or less, 8.0 or less, 7.7 or less, 7.5 or less, 7.2 or less, 7.0 or less, 6.7 or less, 6.5 or less, 6.2 or less, 6.0 or less, 5.7 or less, 5.5 or less, 5.2 or less, 5.0 or less, 4.7 or less, 4.5 or less, 4.2 or less, 4.0 or less, 3.7 or less, 3.5 or less, 3.2 or less, 3.0 or less, 2.7 or less, 2.5 or less, 2.2 or less, 2.0 or less, 1.7 or less, 1.5 or less, or 1.2 or less.

The content mass ratio of the component (A) to the component (B) (component (A)/component (B)) in the polishing composition is preferably 10.0 or more, and is sequentially more preferably 40.0 or more, 60.0 or more, 70.0 or more, 80.0 or more, 100.0 or more, or 200.0 or more, from the viewpoint of a further enhancement in polishing removal rate of an object to be polished. The content mass ratio of the component (A) to the component (B) (component (A)/component (B)) in the polishing composition is preferably 350.0 or less, and is sequentially more preferably 320.0 or less, 300.0 or less, 290.0 or less, 280.0 or less, or 270.0 or less, from the same viewpoint. The content mass ratio of the component (A) to the component (B) (component (A)/component (B)) in the polishing composition is preferably 10.0 or more and 350.0 or less, and is sequentially more preferably 40.0 or more and 320.0 or less, 60.0 or more and 300.0 or less, 70.0 or more and 300.0 or less, 80.0 or more and 300.0 or less, 100.0 or more and 290.0 or less, 100.0 or more and 280.0 or more, or 200.0 or more and 270.0 or less, from the viewpoint of a further enhancement in polishing removal rate of an object to be polished.

The content mass ratio of the component (A) to the component (B) (component (A)/component (B)) in the polishing composition is preferably 2.0 or more, and is sequentially more preferably 5.0 or more, 10.0 or more, more than 10.0, 15.0 or more, 20.0 or more, or 30.0 or more, from the viewpoint of a more enhancement in the balance among an excellent unevenness elimination ability on an object to be polished, an enhancement in polishing removal rate of an object to be polished, and a defect reduction on a surface of a polished object. The content mass ratio of the component (A) to the component (B) (component (A)/component (B)) in the polishing composition is preferably 100.0 or less, and is sequentially more preferably 90.0 or less, 60.0 or less, 50.0 or less, 45.0 or less, or 40.0 or less, from the same viewpoint. The content mass ratio of the component (A) to the component (B) (component (A)/component (B)) in the polishing composition is preferably 2.0 or more and 100.0 or less, and is sequentially more preferably 5.0 or more and 90.0 or less, 10.0 or more and 90.0 or less, more than 10.0 and 60.0 or less, 15.0 or more and 60.0 or less, 20.0 or more and 50.0 or less, 20.0 or more and 45.0 or less, or 30.0 or more and 40.0 or less, from the viewpoint of a more enhancement in the balance among an excellent unevenness elimination ability on an object to be polished, an enhancement in polishing removal rate of an object to be polished, and a defect reduction on a surface of a polished object.

As described above, in a case where the polishing composition contains two or more such components (A), the content of the component (A) means the total amount of such components (A). Similarly, in a case where the polishing composition contains two or more such components (B), the content of the component (B) means the total amount of such components (B).

The polishing composition according to the present disclosure is substantially free of an abrasive grain. Herein, “is substantially free of an abrasive grain” encompasses not only a case where an abrasive grain is not contained in the polishing composition at all (the concentration is 0% by mass), but also a case where an abrasive grain is contained at a proportion of preferably more than 0% by mass and 0.1% by mass or less, more preferably more than 0% by mass and 0.01% by mass or less, further preferably more than 0% by mass (0 ppm by mass) and 10 ppm by mass or less, for example, more than 0% by mass (0 ppm by mass) and 1 ppm by mass or less in the polishing composition.

### [pH and pH Adjusting Agent]

The pH of the polishing composition according to the present disclosure is 8 or more. If the pH is less than 8, the polishing removal rate of an object to be polished is lowered.

The pH of the polishing composition is preferably 8.1 or more, and can be 8.15 or more, 8.2 or more, 8.25 or more, 8.3 or more, 8.35 or more, 8.4 or more, 8.45 or more, 8.5 or more, 8.55 or more, 8.6 or more, 8.65 or more, 8.7 or more, 8.75 or more, 8.8 or more, 8.85 or more, 8.9 or more, 8.95 or more, 9 or more, 9.05 or more, 9.1 or more, 9.15 or more, 9.2 or more, 9.25 or more, 9.3 or more, 9.35 or more, 9.4 or more, 9.45 or more, 9.5 or more, 9.55 or more, 9.6 or more, 9.65 or more, 9.7 or more, 9.75 or more, 9.8 or more, 9.85 or more, 9.9 or more, 9.95 or more, 10 or more, 10.05 or more, 10.1 or more, 10.15 or more, 10.2 or more, 10.25 or more, 10.3 or more, 10.35 or more, 10.4 or more, 10.45 or more, 10.5 or more, 10.55 or more, 10.6 or more, 10.65 or more, 10.7 or more, 10.75 or more, 10.8 or more, 10.85 or more, 10.9 or more, 10.95 or more, 11 or more, 11.05 or more, 11.1 or more, 11.15 or more, 11.2 or more, 11.25 or more, 11.3 or more, 11.35 or more, 11.4 or more, 11.45 or more, 11.5 or more, 11.55 or more, 11.6 or more, 11.65 or more, 11.7 or more, 11.75 or more, 11.8 or more, 11.85 or more, 11.9 or more, or 11.95 or more.

The pH of the polishing composition is preferably 12 or less, and can be 11.95 or less, 11.9 or less, 11.85 or less, 11.8 or less, 11.75 or less, 11.7 or less, 11.65 or less, 11.6 or less, 11.55 or less, 11.5 or less, 11.45 or less, 11.4 or less, 11.35 or less, 11.3 or less, 11.25 or less, 11.2 or less, 11.15 or less, 11.1 or less, 11.05 or less, 11 or less, 10.95 or less, 10.9 or less, 10.85 or less, 10.8 or less, 10.75 or less, 10.7 or less, 10.65 or less, 10.6 or less, 10.55 or less, 10.5 or less, 10.45 or less, 10.4 or less, 10.35 or less, 10.3 or less, 10.25 or less, 10.2 or less, 10.15 or less, 10.1 or less, 10.05 or less, 10 or less, 9.95 or less, 9.9 or less, 9.85 or less, 9.8 or less, 9.75 or less, 9.7 or less, 9.65 or less, 9.6 or less, 9.55 or less, 9.5 or less, 9.45 or less, 9.4 or less, 9.35 or less, 9.3 or less, 9.25 or less, 9.2 or less, 9.15 or less, 9.1 or less, 9.05 or less, 9 or less, 8.95 or less, 8.9 or less, 8.85 or less, 8.8 or less, 8.75 or less, 8.7 or less, 8.65 or less, 8.6 or less, 8.55 or less, 8.5 or less, 8.45 or less, 8.4 or less, 8.35 or less, 8.3 or less, 8.25 or less, 8.2 or less, 8.15 or less, or 8.1 or less. When the pH of the polishing composition is 12 or less, the surface roughness of an object to be polished after polishing can be decreased.

The component (A) in the present disclosure can serve as a pH adjusting agent. Accordingly, the polishing composition according to the present disclosure optionally does not contain a pH adjusting agent for adjusting the pH. However, in a case where the desired pH is not achieved by only the component (A), the polishing composition of the present disclosure may contain a pH adjusting agent other than the component (A). The pH adjusting agent may be any of an inorganic acid, an organic acid, an inorganic base, and an organic base. The pH adjusting agent may be used singly or in combinations of two or more kinds thereof.

Specific examples of the inorganic acid usable as the pH adjusting agent include hydrochloric acid, sulfuric acid, nitric acid, hydrofluoric acid, boric acid, carbonic acid, hypophosphorous acid, phosphorus acid, and phosphoric acid. Specific examples of the organic acid usable as the pH adjusting agent include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, phenoxyacetic acid, methanesulfonic acid, ethanesulfonic acid, and isethionic acid.

Specific examples of the base usable as the pH adjusting agent can include inorganic bases such as ammonia, sodium hydroxide, and potassium hydroxide, and organic bases such as tetramethylammonium hydroxide. The amount of addition of the pH adjusting agent is not particularly limited, and may be appropriately adjusted so that the polishing composition has a desired pH.

The pH of the polishing composition can be measured with, for example, a pH meter, and specifically can be measured by a method described in Examples.

### [Dispersing Medium]

The polishing composition according to the present disclosure preferably contains a dispersing medium for dispersing each component. Examples of the dispersing medium can include water; alcohols such as methanol, ethanol, and ethylene glycol; ketones such as acetone, and any mixture thereof. In particular, the dispersing medium is preferably water. In other words, according to a preferred mode of the present disclosure, the dispersing medium includes water. According to a more preferred mode of the present disclosure, the dispersing medium is substantially composed of water. Herein, “substantially” means that any other dispersing medium than water can be contained as long as the effects of the present disclosure are achieved. More specifically, the dispersing medium preferably contains 90% by mass or more and 100% by mass or less of water and 0% by mass or more and 10% by mass or less of any other dispersing medium than water, more preferably contains 99% by mass or more and 100% by mass or less of water and 0% by mass or more and 1% by mass or less of any other dispersing medium than water. The dispersing medium is most preferably water.

The dispersing medium is preferably water not containing impurities as much as possible from the viewpoint of not inhibiting the effects of the components contained in the polishing composition. Specifically, the dispersing medium is more preferably ion exchanged water (deionized water), pure water or ultrapure water obtained by removing impurity ions with an ion exchange resin and then removing foreign substances through a filter, or distilled water.

### [Electrical Conductivity of Polishing Composition]

The electrical conductivity (EC) of the polishing composition according to the present disclosure is not particularly limited, and is preferably 0.1 mS/cm or more, and can be 0.2 mS/cm or more, 0.3 mS/cm or more, 0.4 mS/cm or more, 0.5 mS/cm or more, 0.6 mS/cm or more, 0.7 mS/cm or more, 0.8 mS/cm or more, 0.9 mS/cm or more, 1.0 mS/cm or more, 1.1 mS/cm or more, 1.2 mS/cm or more, 1.3 mS/cm or more, 1.4 mS/cm or more, 1.5 mS/cm or more, 1.6 mS/cm or more, 1.7 mS/cm or more, 1.8 mS/cm or more, 1.9 mS/cm or more, 2.0 mS/cm or more, 2.1 mS/cm or more, 2.2 mS/cm or more, 2.3 mS/cm or more, 2.4 mS/cm or more, 2.5 mS/cm or more, 2.6 mS/cm or more, 2.7 mS/cm or more, 2.8 mS/cm or more, 2.9 mS/cm or more, 3.0 mS/cm or more, 3.1 mS/cm or more, 3.2 mS/cm or more, 3.3 mS/cm or more, 3.4 mS/cm or more, 3.5 mS/cm or more, 3.6 mS/cm or more, 3.7 mS/cm or more, 3.8 mS/cm or more, 3.9 mS/cm or more, 4.0 mS/cm or more, 4.2 mS/cm or more, 4.4 mS/cm or more, 4.6 mS/cm or more, 4.8 mS/cm or more, 5.0 mS/cm or more, 5.2 mS/cm or more, 5.4 mS/cm or more, 5.6 mS/cm or more, 5.8 mS/cm or more, 6.0 mS/cm or more, 6.2 mS/cm or more, 6.4 mS/cm or more, 6.6 mS/cm or more, 6.8 mS/cm or more, 7.0 mS/cm or more, 7.2 mS/cm or more, 7.4 mS/cm or more, 7.6 mS/cm or more, 7.8 mS/cm or more, 8.0 mS/cm or more, 8.2 mS/cm or more, 8.4 mS/cm or more, 8.6 mS/cm or more, 8.8 mS/cm or more, 9.0 mS/cm or more, 9.2 mS/cm or more, 9.4 mS/cm or more, 9.6 mS/cm or more, 9.8 mS/cm or more, 10.0 mS/cm or more, 10.2 mS/cm or more, 10.4 mS/cm or more, 10.6 mS/cm or more, 10.8 mS/cm or more, 11.0 mS/cm or more, 11.2 mS/cm or more, 11.4 mS/cm or more, 11.6 mS/cm or more, 11.8 mS/cm or more, 12.0 mS/cm or more, 12.2 mS/cm or more, 12.4 mS/cm or more, 12.6 mS/cm or more, 12.8 mS/cm or more, 13.0 mS/cm or more, 13.2 mS/cm or more, 13.4 mS/cm or more, 13.6 mS/cm or more, 13.8 mS/cm or more, 14.0 mS/cm or more, 14.2 mS/cm or more, 14.4 mS/cm or more, 14.6 mS/cm or more, 14.8 mS/cm or more, 15.0 mS/cm or more, 15.5 mS/cm or more, 16.0 mS/cm or more, 16.5 mS/cm or more, 17.0 mS/cm or more, 17.5 mS/cm or more, 18.0 mS/cm or more, 18.5 mS/cm or more, 19.0 mS/cm or more, or 19.5 mS/cm or more.

The electrical conductivity (EC) of the polishing composition according to the present disclosure is not particularly limited, and is preferably 20 mS/cm or less, and can be 19.8 mS/cm or less, 19.6 mS/cm or less, 19.4 mS/cm or less, 19.2 mS/cm or less, 19.0 mS/or less, 18.8 mS/cm or less, 18.6 mS/cm or less, 18.4 mS/cm or less, 18.2 mS/cm or less, 18.0 mS/or less, 17.8 mS/cm or less, 17.6 mS/cm or less, 17.4 mS/cm or less, 17.2 mS/cm or less, 17.0 mS/or less, 16.8 mS/cm or less, 16.6 mS/cm or less, 16.4 mS/cm or less, 16.2 mS/cm or less, 16.0 mS/or less, 15.8 mS/cm or less, 15.6 mS/cm or less, 15.4 mS/cm or less, 15.2 mS/cm or less, 15.0 mS/or less, 14.8 mS/cm or less, 14.6 mS/cm or less, 14.4 mS/cm or less, 14.2 mS/cm or less, 14.0 mS/or less, 13.8 mS/cm or less, 13.6 mS/cm or less, 13.4 mS/cm or less, 13.2 mS/cm or less, 13.0 mS/or less, 12.8 mS/cm or less, 12.6 mS/cm or less, 12.4 mS/cm or less, 12.2 mS/cm or less, 12.0 mS/or less, 11.8 mS/cm or less, 11.6 mS/cm or less, 11.4 mS/cm or less, 11.2 mS/cm or less, 11.0 mS/or less, 10.8 mS/cm or less, 10.6 mS/cm or less, 10.4 mS/cm or less, 10.2 mS/cm or less, 10.0 mS/or less, 9.8 mS/cm or less, 9.6 mS/cm or less, 9.4 mS/cm or less, 9.2 mS/cm or less, 9.0 mS/or less, 8.8 mS/cm or less, 8.6 mS/cm or less, 8.4 mS/cm or less, 8.2 mS/cm or less, 8.0 mS/or less, 7.8 mS/cm or less, 7.6 mS/cm or less, 7.4 mS/cm or less, 7.2 mS/cm or less, 7.0 mS/or less, 6.8 mS/cm or less, 6.6 mS/cm or less, 6.4 mS/cm or less, 6.2 mS/cm or less, 6.0 mS/or less, 5.8 mS/cm or less, 5.6 mS/cm or less, 5.4 mS/cm or less, 5.2 mS/cm or less, 5.0 mS/or less, 4.8 mS/cm or less, 4.6 mS/cm or less, 4.4 mS/cm or less, 4.2 mS/cm or less, 4.0 mS/or less, 3.9 mS/cm or less, 3.8 mS/cm or less, 3.7 mS/cm or less, 3.6 mS/cm or less, 3.5 mS/cm or less, 3.4 mS/cm or less, 3.3 mS/cm or less, 3.2 mS/cm or less, 3.1 mS/cm or less, 3.0 mS/cm or less, 2.9 mS/cm or less, 2.8 mS/cm or less, 2.7 mS/cm or less, 2.6 mS/cm or less, 2.5 mS/cm or less, 2.4 mS/cm or less, 2.3 mS/cm or less, 2.2 mS/cm or less, 2.1 mS/cm or less, 2.0 mS/cm or less, 1.9 mS/cm or less, 1.8 mS/cm or less, 1.7 mS/cm or less, 1.6 mS/cm or less, 1.5 mS/cm or less, 1.4 mS/cm or less, 1.3 mS/cm or less, 1.2 mS/cm or less, 1.1 mS/cm or less, 1.0 mS/cm or less, 0.9 mS/cm or less, 0.8 mS/cm or less, 0.7 mS/cm or less, 0.6 mS/cm or less, 0.5 mS/cm or less, 0.4 mS/cm or less, 0.3 mS/cm or less, or 0.2 mS/cm or less. When the electrical conductivity (EC) of the polishing composition is 20 mS/cm or less, the number of defects can be reduced and the surface roughness of an object to be polished after polishing can be decreased.

When the electrical conductivity of the polishing composition falls within the above range, the polishing removal rate of an object to be polished can be more enhanced. The electrical conductivity of the polishing composition can be adjusted with the type, the concentration, and/or the like of the pH adjusting agent. The electrical conductivity of the polishing composition can be measured by a method described in Examples.

The polishing composition according to the present disclosure may further contain an electrical conductivity adjusting agent for adjusting the electrical conductivity. The electrical conductivity adjusting agent is not particularly limited as long as it is a compound having the function of adjusting the electrical conductivity, and, for example, a salt compound can be used. Examples of the salt compound include a salt of an acid compound and a salt of a basic compound. The salt of an acid compound may be an organic acid salt or an inorganic acid salt.

Specific examples of the electrical conductivity adjusting agent include sodium nitrate, potassium nitrate, ammonium nitrate, magnesium nitrate, calcium nitrate, sodium nitrite, potassium nitrite, lithium acetate, sodium acetate, potassium acetate, ammonium acetate, calcium acetate, calcium lactate, lithium benzoate, sodium benzoate, potassium benzoate, lithium carbonate, sodium carbonate, potassium carbonate, magnesium carbonate, calcium carbonate, lithium hydrogen carbonate, sodium hydrogen carbonate, potassium hydrogen carbonate, ammonium carbonate, sodium bicarbonate, sodium sulfate, potassium sulfate, ammonium sulfate, calcium sulfate, magnesium sulfate, sodium sulfite, potassium sulfite, calcium sulfite, magnesium sulfite, potassium thiosulfate, lithium sulfate, magnesium sulfate, sodium thiosulfate, sodium hydrogen sulfite, sodium hydrogen sulfate, potassium hydrogen sulfate, disodium oxalate, dipotassium oxalate, ammonium oxalate, ammonium citrate, disodium glutarate, lithium fluoride, sodium fluoride, potassium fluoride, calcium fluoride, ammonium fluoride, potassium chloride, sodium chloride, ammonium chloride, calcium chloride, potassium bromide, sodium bromide, ammonium bromide, calcium bromide, sodium iodide, potassium iodide, potassium triiodide, calcium iodide, trilithium phosphate, tripotassium phosphate, trisodium phosphate, triammonium phosphate, sodium monohydrogen phosphate, potassium monohydrogen phosphate, sodium dihydrogen phosphate, potassium dihydrogen phosphate, and ammonium dihydrogen phosphate. Such electrical conductivity adjusting agents may be used singly or in combinations of two or more kinds thereof.

The concentration (content) of the electrical conductivity adjusting agent may be an amount appropriately selected so as to be a preferred electrical conductivity value for the polishing composition. According to some embodiments, the concentration (content) of the electrical conductivity adjusting agent, under the assumption that the total mass of the polishing composition is 100% by mass, is preferably 0.01% by mass or more, more preferably 0.05% by mass or more. The concentration (content) of the electrical conductivity adjusting agent, under the assumption that the total mass of the polishing composition is 100% by mass, is preferably 3.0% by mass or less, more preferably 2.0% by mass or less. In other words, the concentration (content) of the electrical conductivity adjusting agent, under the assumption that the total mass of the polishing composition is 100% by mass, is preferably 0.01% by mass or more and 3.0% by mass or less, more preferably 0.05% by mass or more and 2.0% by mass or less. In a case where the polishing composition contains two or more such electrical conductivity adjusting agents, the concentration (content) of the electrical conductivity adjusting agent means the total amount of such electrical conductivity adjusting agents.

### [Other Components]

The polishing composition according to the present disclosure may further contain any known additive usable for polishing compositions, such as a complexing agent, an antiseptic agent, a surfactant, an antifungal agent, and/or an oxidizing agent as long as the effects of the present disclosure are not impaired. According to one embodiment of the present disclosure, the polishing composition may further contain an antifungal agent. In other words, in one embodiment of the present disclosure, the polishing composition is substantially constituted from the (A) amine compound having a heterocyclic structure containing two or more nitrogen atoms, the (B) water-soluble polymer, the dispersing medium, and at least one selected from the pH adjusting agent, the electrical conductivity adjusting agent, and an antifungal agent. In one embodiment of the present disclosure, the polishing composition is substantially constituted from the (A) amine compound having a heterocyclic structure containing two or more nitrogen atoms, the (B) water-soluble polymer, the dispersing medium, the pH adjusting agent, and the electrical conductivity adjusting agent. In one embodiment of the present disclosure, the polishing composition is substantially constituted from the (A) amine compound having a heterocyclic structure containing two or more nitrogen atoms, the (B) water-soluble polymer, the dispersing medium, and the pH adjusting agent. Herein, “polishing composition is substantially constituted from the (A) amine compound having a heterocyclic structure containing two or more nitrogen atoms, the (B) water-soluble polymer, the dispersing medium, and at least one selected from the pH adjusting agent, the electrical conductivity adjusting agent, and an antifungal agent” means that the total content of the (A) amine compound having a heterocyclic structure containing two or more nitrogen atoms, the (B) water-soluble polymer, the dispersing medium, the pH adjusting agent, the electrical conductivity adjusting agent, and the antifungal agent is more than 99% by mass (the upper limit: 100% by mass) based on the total mass of the polishing composition. The polishing composition is preferably constituted from the (A) amine compound having a heterocyclic structure containing two or more nitrogen atoms, the (B) water-soluble polymer, the dispersing medium, the pH adjusting agent, and the electrical conductivity adjusting agent (the total content=100% by mass).

Examples of the antifungal agent (antiseptic agent) which can be added to the polishing composition according to the present disclosure include 1,2-benzoisothiazol-3 (2H)-one (BIT); isothiazoline-based antiseptic agents such as 2-methyl-4-isothiazolin-3-one and 5-chloro-2-methyl-4-isothiazolin-3-one; paraoxybenzoates; and phenoxyethanol. Such antifungal agents may be used singly or in combinations of two or more kinds thereof.

### [Method for Producing Polishing Composition]

The method for producing the polishing composition according to the present disclosure is not particularly limited, and the polishing composition can be obtained by, for example, stirring and mixing the component (A), the component (B), and, if necessary, other additive in the dispersing medium (for example, water). The detail of each of the components is as described above.

The temperature during mixing of each of the components is not particularly limited, and is preferably 10° C. or more and 40° C. or less, and heating may also be performed for increasing the rate of dissolution. The mixing time is also not particularly limited as long as uniform mixing can be made.

### [Object to be Polished]

A polishing composition according to one embodiment of the present disclosure can be applied to a known object to be polished which is not particularly limited and which is used in the CMP field. Therefore, an aspect of the object to be polished is not particularly limited, a layer being a flat-plate-like member is preferred, a substrate including the layer is more preferred, and a semiconductor substrate is further preferred. Examples include a substrate constituted from a single layer, and a substrate including a layer to be polished and any other layer (for example, a support layer or any other functional layer). Examples of the material constituting the object to be polished include, but not particularly limited thereto, a silicon-containing material and a metal-containing material (for example, a metal simple substance, metal oxide, and metal nitride). The material constituting the object to be polished may be used singly or in combinations of two or more kinds thereof.

Examples of the silicon-containing material include, but not particularly limited thereto, a material having a silicon-oxygen bond, a material having a silicon-silicon bond, and a material having a silicon-nitrogen bond. Examples of the material having a silicon-oxygen bond include, but not particularly limited thereto, silicon oxide, BD (black diamond: SiOCH), FSG (fluorosilicate glass), HSQ (hydrogen silsesquioxane), CYCLOTENE, SiLK, and MSQ (Methyl silsesquioxane). Examples of the object to be polished having a silicon-silicon bond include, but not particularly limited thereto, polycrystalline silicon (polysilicon, Poly-Si), amorphous silicon (a-Si), monocrystalline silicon, n-type doped monocrystalline silicon, p-type doped monocrystalline silicon, ana Si-based alloys such as SiGe. Examples of the material having a silicon-nitrogen bond include, but not particularly limited thereto, silicon nitride and silicon carbonitride (SiCN).

Among such silicon-containing materials, the object to be polished is preferably the material having a silicon-silicon bond, more preferably amorphous silicon. The object to be polished may contain not only the material having a silicon-silicon bond, but also the material having a silicon-nitrogen bond. A film containing material having a silicon-nitrogen bond can be used as a stop film.

### [Method for Producing Substrate]

As described above, the polishing composition according to the present disclosure is suitably used for polishing of an object to be polished containing a material having a silicon-silicon bond. Accordingly, the present disclosure provides a polishing method including a step of polishing an object to be polished containing a material having a silicon-silicon bond, with the polishing composition according to the present disclosure. The present disclosure also provides a method for producing a substrate, the method including polishing an object to be polished containing a material having a silicon-silicon bond by the polishing method according to the present disclosure.

It is preferable for efficiently obtaining the effects of the present disclosure to include, before the above polishing step, a step of removing a natural oxide film formed on a surface of an object to be polished containing a material having a silicon-silicon bond. The shore D hardness of a polishing pad used in the polishing step is preferably 30 or more. In other words, according to one preferred embodiment of the present disclosure, there is provided a method for producing a substrate, the method including a step of removing a natural oxide film on a surface of an object to be polished containing a material having a silicon-silicon bond, and a step of polishing the object to be polished containing a material having a silicon-silicon bond, with the polishing composition according to the present disclosure and a polishing pad having a shore D hardness of 30 or more. Hereinafter, the method for producing a substrate is described in the order of the steps.

### (Step of Removing Natural Oxide Film)

The present step is a step of removing a natural oxide film on a surface of an object to be polished containing a material having a silicon-silicon bond.

The surface of an object to be polished containing a material having a silicon-silicon bond is naturally oxidized over time to generate a silicon oxide film. The silicon oxide film thus naturally generated is referred to as “natural oxide film”.

According to one embodiment of the present disclosure, the object to be polished to be subjected to the present step is more specifically a semiconductor substrate which has a surface layer containing a material having a silicon-silicon bond and in which the natural oxide film is attached to at least one portion of the surface layer.

The removal method carried out in the step of removing the natural oxide film is not particularly limited, and examples include a method to be performed by polishing and a method to be performed by etching. More specifically, examples of the method to be performed by polishing include a method by polishing with a polishing composition containing an abrasive grain and, if necessary, any other component. Examples of the method to be performed by etching include a method including coating at least a surface of the object to be polished with an etching liquid for selectively etching the natural oxide film, to corrode and remove the natural oxide film. Hereinafter, these two methods are described.

<Method of Polishing with Polishing Composition>

Examples of the type of the abrasive grain contained in the polishing composition used for removal of the natural oxide film include metal oxides such as silica, alumina, zirconia, ceria, and titania. In order to efficiently exert the intended effects of the present disclosure, silica is preferred. The type of such silica as a suitable example is not particularly limited, and examples include colloidal silica, fumed silica, and sol-gel method silica. In particular, colloidal silica is more preferred, colloidal silica in which an organic acid is chemically bonded onto a surface is further preferred, and colloidal silica in which sulfonic acid is chemically bonded onto a surface is particularly preferred. Examples of any other component contained in the polishing composition include a dispersing medium and an acid compound.

The polishing apparatus, the number of rotations of a polishing table, the polishing pressure, and the like during removal of the natural oxide film are not particularly limited, and are, for example, the same apparatus and conditions as conditions described with respect to a polishing step described below.

### <Method by Etching>

The etching liquid used for removal of the natural oxide film is preferably a composition containing at least one acidic substance selected from hydrofluoric acid (HF), ammonium fluoride (NH₄F), ammonium hydrogen fluoride, BHF (mixture of HF and NH₄F; buffered hydrofluoric acid), or DHF (mixture of HF and H₂O). The etching liquid preferably contains water as a solvent. A water-soluble organic solvent (for example, lactone or a polyhydric alcohol) may also be contained together with water.

The concentration (content) of the acidic substance in the etching liquid is, as one example, 0.05% by mass or more and 99% by mass or less, may be 0.3% by mass or more and 30% by mass or less, or may be 0.5% by mass or more and 5% by mass or less.

Examples of the method for coating with the etching liquid include the following method:
(1) A method involving dipping the object to be polished in the etching liquid (namely, dipping method)

(2) A method involving coating a surface of the object to be polished with the etching liquid (namely, coating method).

In the dipping method (1), the dipping time is, for example, 0.5 to 30 seconds. The dipping temperature (for example, the temperature of the etching liquid during dipping) is, for example, 20 to 30° C. The dipping method can suppress the amount of use of the etching liquid and is an economical method. The method is also high in productivity because of being capable of speedily applying etching treatment.

Examples of the method for coating a surface of the object to be polished with the etching liquid in the coating method (2) include a spin coating method, stamping, dispensing, a squeegeeing method, spraying, and brush coating. The coating method can inhibit unnecessary corrosion from occurring with the etching liquid. Coating conditions are not particularly limited.

### (Polishing Step of Object to be Polished)

The polishing apparatus used here can be a common polishing apparatus in which a holder holding a substrate or the like having an object to be polished and a motor or the like changeable in number of rotations are installed and which has a polishing table to which a polishing pad (polishing cloth) can be attached.

The type of the polishing pad used in each of the polishing method and the method for producing a substrate, according to the present disclosure, is not particularly limited, and can be, for example, an expanded polyurethane type, a non-woven cloth type, or a swede type.

The shore D hardness of the polishing pad is preferably 30 or more. When the shore D hardness is 30 or more, the pressure applicable to an object to be polished can be increased and the polishing removal rate is more enhanced. The shore D hardness of the polishing pad is more preferably 40 or more, further preferably 50 or more. The shore D hardness of the polishing pad is preferably 90 or less, more preferably 80 or less, further preferably 70 or less. When the shore D hardness is 90 or less, the polishing pad can well follow an object to be polished surface during polishing and polishing can be stably performed. The shore D hardness can be measured by a method described in JIS K 7215:1986.

Among polishing conditions, for example, the rotational speed of a polishing table is preferably 10 rpm (0.17 s⁻¹) or more and 500 rpm (8.33 s⁻¹). The pressure (polishing pressure) applied to a substrate having an object to be polished is preferably 0.5 psi (3.4 kPa) or more and 10 psi (68.9 kPa). The method for supplying the polishing composition to the polishing pad is also not particularly limited, and, for example, a continuously supplying method with a pump or the like is adopted. The amount of this supplying is not limited, and a surface of the polishing pad is preferably always covered with the polishing composition according to the present disclosure.

After completion of polishing, a substrate is washed in flowing water and water droplets attached onto the substrate are blown away with a spin dryer or the like, thereby providing a substrate containing a material having a silicon-silicon bond.

The polishing composition according to the present disclosure may be of one-liquid-type, or of multi-liquid type including two-liquid type. The polishing composition according to the present disclosure may also be prepared by diluting a stock solution of the polishing composition with a dilution liquid such as water to, for example, two times or more and 10 times or less.

### [Polishing System]

Another embodiment of the present disclosure provides a polishing system including an object to be polished containing a material having a silicon-silicon bond, a polishing pad having a shore D hardness of 30 or more, and a polishing composition, wherein the polishing composition contains (A) an amine compound having a heterocyclic structure containing two or more nitrogen atoms, and (B) a water-soluble polymer, the content mass ratio of the component (A) to the component (B) (component (A)/component (B)) is 1 or more, the polishing composition has a pH of 8 or more, and the polishing composition is substantially free of an abrasive grain, and wherein a surface of the object to be polished is contacted with the polishing pad and the polishing composition.

The object to be polished and the polishing composition applied to the polishing system of the present disclosure are the same as described above, and the descriptions thereof are here omitted.

The type of the polishing pad used in the polishing system of the present disclosure is not particularly limited, and can be, for example, an expanded polyurethane type, a non-woven cloth type, or a swede type.

The shore D hardness of the polishing pad is preferably 30 or more. When the shore D hardness is 30 or more, the pressure applicable to the object to be polished can be increased and the polishing removal rate is more enhanced. The shore D hardness of the polishing pad is more preferably 40 or more, further preferably 50 or more. The shore D hardness of the polishing pad is preferably 90 or less, more preferably 80 or less, further preferably 70 or less. When the shore D hardness is 90 or less, the polishing pad can well follow an object to be polished surface during polishing and polishing can be stably performed. The shore D hardness can be measured by a method described in JIS K 7215:1986.

The polishing system of the present disclosure may be one in which both surfaces of the object to be polished are contacted with the polishing pad and the polishing composition to simultaneously polish such both surfaces of the object to be polished, or may be one in which only one surface of the object to be polished is contacted with the polishing pad and the polishing composition to polish only such one surface of the object to be polished.

In the polishing system of the present disclosure, a working slurry containing the polishing composition is prepared. Next, the polishing composition is supplied to the object to be polished, to polish the object to be polished by an ordinary method. For example, the object to be polished is installed in a common polishing apparatus, and the polishing composition is supplied to a surface of the object to be polished (surface to be polished), with a polishing pad of the polishing apparatus being interposed. Typically, while the polishing composition is continuously supplied, the polishing pad is pushed toward a surface of the object to be polished and both are relatively moved (for example, rotated and moved). Such a polishing step is conducted to complete polishing of the object to be polished.

Among polishing conditions, for example, the rotational speed of a polishing table is preferably 10 rpm (0.17 s⁻¹) or more and 500 rpm (8.3 s⁻¹) or less. The pressure (polishing pressure) applied to a substrate having the object to be polished is preferably 0.5 psi (3.4 kPa) or more and 10 psi (68.9 kPa) or less. The method for supplying the polishing composition to the polishing pad is also not particularly limited, and, for example, a continuously supplying method with a pump or the like is adopted. The amount of this supplying is not limited, and a surface of the polishing pad is preferably always covered with the polishing composition of the present disclosure.

### [Polishing Removal Rate]

The polishing method according to the present disclosure can polish an object to be polished containing a material having a silicon-silicon bond at a higher polishing removal rate. The polishing method according to the present disclosure is preferably applied to polishing of the object to be polished containing a material having a silicon-silicon bond.

The lower limit of the polishing removal rate of such a material containing a silicon-silicon bond is preferably 1000 Å/min or more, more preferably 1500 Å/min or more, further preferably 2000 Å/min or more.

### [Unevenness Elimination Ability]

A polishing method with a polishing composition according to one preferred embodiment of the present disclosure includes polishing a surface of an object to be polished containing a material having a silicon-silicon bond, with the above-mentioned polishing composition. Thus, polishing characteristics of the object to be polished can be more enhanced. In particular, in a case where unevenness due to multi-layering of wires, or the like, for example, initial unevenness is generated on a surface of a substrate, the unevenness elimination ability can be enhanced. The unevenness elimination ability can be evaluated as the unevenness elimination efficiency determined as “(the amount (Å) of a portion corresponding to the height of unevenness eliminated by polishing in a certain polishing process (in one depressed portion, the height (Å) from the lowest portion of the depressed portion to the uppermost portion of a protruded portion constituting the depressed portion)) (the amount of unevenness elimination)/(the total amount of polishing in the polishing process (the distance (A) from the height of the uppermost portion of the protruded portion before polishing to the height of the uppermost portion of the protruded portion after polishing))”. As such a value is closer to 1, only an upper surface of the protruded portion can be selectively polished to make the polishing efficiency more excellent. The unevenness elimination efficiency is preferably 0.15 (15%) or more, more preferably 0.2 (20%) or more, further preferably 0.25 (25%) or more in the case of polishing in polishing conditions of, for example, a polishing pressure of 2.5 psi (17.2 kPa) and a number of polishing table rotations of 90 rpm (1.5 s⁻¹).

Although embodiments of the present disclosure are described in detail, it is clear that these embodiments are descriptive and illustrative and are not limiting and the scope of the present disclosure is to be interpreted by the accompanying claims.

The present disclosure encompasses the following aspects and modes.
[1] A polishing composition comprising
(A) an amine compound having a heterocyclic structure containing two or more nitrogen atoms, and
(B) a water-soluble polymer,
wherein a content mass ratio of the component (A) to the component (B) (component (A)/component (B)) is 1 or more,
the polishing composition has a pH of 8 or more, and
the polishing composition is substantially free of an abrasive grain;
[2] The polishing composition according to [1], wherein the (A) amine compound having a heterocyclic structure containing two or more nitrogen atoms comprises at least one selected from the group consisting of a compound having an imidazole ring structure, a compound having an aliphatic polycyclic structure, and a compound having a piperazine ring structure;
[3] The polishing composition according to [1] or [2], wherein the (A) amine compound having a heterocyclic structure containing two or more nitrogen atoms comprises at least one selected from the group consisting of imidazole, 1,4-diazabicyclo[2.2.2]octane, and 1-(2-aminoethyl) piperazine;
[4] The polishing composition according to any of [1] to [3], wherein the (B) water-soluble polymer comprises a non-ionic polymer;
[5] The polishing composition according to [4], wherein the non-ionic polymer comprises polyvinylpyrrolidone;
[6] The polishing composition according to any of [1] to [5], further comprising a dispersing medium;
[7] The polishing composition according to any of [1] to [6], for use in the which is used for polishing of an object to be polished containing a material having a silicon-silicon bond;
[8] The polishing composition according to [7], wherein the material having a silicon-silicon bond is amorphous silicon;
[9] A method for producing a substrate, comprising
a step of removing a natural oxide film on a surface of an object to be polished containing a material having a silicon-silicon bond, and
a step of polishing the object to be polished containing a material having a silicon-silicon bond, with the polishing composition according to any of [1] to [8] and a polishing pad having a shore D hardness of 30 or more;
[10] The method for producing a substrate according to [9], comprising performing the step of removing the natural oxide film, by polishing;
[11] The method for producing a substrate according to [9] or [10], comprising performing the step of removing the natural oxide film, by etching;
[12] A polishing system comprising an object to be polished containing a material having a silicon-silicon bond, a polishing pad having a shore D hardness of 30 or more, and a polishing composition,
wherein the polishing composition comprises
   (A) an amine compound having a heterocyclic structure containing two or more nitrogen atoms, and
   (B) a water-soluble polymer, a content mass ratio of the component (A) to the component (B) (component (A)/component (B)) is 1 or more, the polishing composition has a pH of 8 or more, and the polishing composition is substantially free of an abrasive grain, and
wherein a surface of the object to be polished is contacted with the polishing pad and the polishing composition.

### EXAMPLES

The present disclosure is described in further detail with reference to the following Examples and Comparative Examples. It is noted that the technical scope of the present disclosure is not limited to only the following Examples. Unless particularly noted, “%” and “part(s)” respectively mean “% by mass” and “part(s) by mass”.

### <Weight Average Molecular Weight of Water-Soluble Polymer>

The weight average molecular weight of the water-soluble polymer was measured by gel permeation chromatography (GPC) with polyethylene glycol as a standard substance. The detail conditions are as described below:
GPC apparatus: manufactured by Shimadzu Corporation
Model: Prominence+ELSD detector (ELSD-LTII)
Column: VP-ODS (manufactured by Shimadzu Corporation)
Mobile phase A: MeOH
   B: aqueous 1% acetic acid solution
Flow rate: 1 mL/min
Detector: ELSD temp. 40° C., Gain 8, N₂GAS 350 kPa
Oven temperature: 40° C.
Amount of injection: 40 μl.

### <pH of Polishing Composition>

The pH of the polishing composition was measured as a value at 25° C. with a pH meter (Model number: LAQUA (registered trademark), manufactured by Horiba Ltd.).

### <Electrical Conductivity of Polishing Composition>

The electrical conductivity (EC) of the polishing composition was measured with a desktop-type electrical conductivity meter (Model number: DS-71, manufactured by Horiba Ltd.).

### <Average Primary Particle Size of Abrasive Grain>

The average primary particle size of the abrasive grain was calculated from the specific surface area of a silica particle according to a BET method, as measured with “Flow Sorb II 2300” manufactured by Micromeritics Instrument Corporation, and the density of the abrasive grain.

### <Average Secondary Particle Size of Abrasive Grain>

The average secondary particle size of the abrasive grain was measured as a volume average particle size, with a laser light scattering measurement apparatus Zetasizer Ultra (manufactured by Malvern Panalytical Ltd.).

### <Components of Polishing Composition>

The detail of the component (B) used for preparation of the polishing composition is as described below:
PVP: polyvinylpyrrolidone, Mw 45,000
PVA: polyvinyl alcohol, Mw 10,000.

### <Object to be Polished>

An object to be polished used for evaluation of the polishing removal rate (object to be polished for polishing removal rate evaluation), prepared here, was each of a silicon wafer (a-Si substrate, diameter 300 mm) where an amorphous silicon film having a thickness of 2000 Å was formed on a surface of the wafer by CVD and a silicon wafer (SiN substrate, diameter 300 mm) where a SiN film having a thickness of 2500 Å was formed on a surface of the wafer.

An object to be polished used for evaluation of the unevenness elimination ability (object to be polished for unevenness elimination ability evaluation), used here, was a silicon wafer where an amorphous silicon film having a thickness of 3000 Å and a pattern of initial unevenness of 800 Å was formed on a surface of the wafer.

Before the polishing step was performed, a natural oxide film on an object to be polished surface was removed by the following polishing or etching method.

### (Removal of Natural Oxide Film: Polishing)

Both the object to be polished for polishing removal rate evaluation and the object to be polished for unevenness elimination ability evaluation, prepared above, were each polished with a polishing composition containing 1.0% by mass of sulfonic acid-modified colloidal silica (average primary particle size: 35 nm, average secondary particle size: 70 nm), 0.5% by mass of maleic acid, and water as the balance, in the following polishing conditions. This polishing removed the natural oxide film on the surface of the object to be polished:

### <Polishing Conditions>

Polishing apparatus: F-REX 300SII manufactured by Ebara Corporation
Polishing pad: expanded polyurethane pad H800 manufactured by Fujibo Holdings Inc.
Dresser: PB32A manufactured by 3M
Polishing time: 30 seconds
Pressure of polishing table: 1 psi (6.89 kPa)
Number of rotations of polishing table: 60 rpm
Number of rotations of carrier: 63 rpm
Supply rate of polishing composition: 200 ml/min.

### <Dressing Conditions>

A dressing operation of the polishing pad was performed with pure water in the following conditions:
(the polishing apparatus, the polishing pad, and the dresser were the same as those in the above <Polishing conditions>)
   Number of rotations of polishing table during dressing operation: 90 rpm
   Pushing force of dresser to polishing table (polishing pad): 22 N
   Dressing operation time: Ex-situ 15 seconds
   Flow rate of pure water flowing during dressing operation: 2,000 ml/min.
   (Removal of natural oxide film: etching)

Both the object to be polished for polishing removal rate evaluation and the object to be polished for unevenness elimination ability evaluation, prepared above, were each subjected to etching in the following conditions, and thus the natural oxide film on the surface of each of the objects to be polished was removed:
Concentration of hydrofluoric acid: 1% by mass
Flow rate of hydrofluoric acid: 1250 ml/min
Treatment time: 60 seconds
Treatment temperature: 20° C.

### Example 1

300 g of ultrapure water was added to 1.0 g of imidazole as the component (A) and the resultant was stirred. Next, 0.1 g of polyvinylpyrrolidone (PVP) as the component (B) and 300 g of ultrapure water were added. Furthermore, ammonia as the pH adjusting agent was added in an amount so that the final pH of the polishing composition was 10.5, and ultrapure water was added so that the total mass of the polishing composition was 1 kg, thereby completing polishing composition 1. After removal of the natural oxide film by polishing was performed, polishing composition 1 was used to perform polishing of the object to be polished (polishing conditions were described below, and the same also applied to the following).

### Example 2

Polishing composition 2 was completed in the same manner as in Example 1 except that the amount of addition of imidazole was changed to 5.0 g. After removal of the natural oxide film by polishing was performed, polishing composition 2 was used to perform polishing of the object to be polished.

### Example 3

Polishing composition 3 was completed in the same manner as in Example 1 except that 1.0 g of 1,4-diazabicyclo[2.2.2]octane (DABCO) was used instead of imidazole. After removal of the natural oxide film by polishing was performed, polishing composition 3 was used to perform polishing of the object to be polished.

### Example 4

Polishing composition 4 was completed in the same manner as in Example 3 except that the amount of addition of 1,4-diazabicyclo[2.2.2]octane (DABCO) was changed to 5.0 g. After removal of the natural oxide film by polishing was performed, polishing composition 4 was used to perform polishing of the object to be polished.

### Example 5

Polishing composition 5 was completed in the same manner as in Example 4 except that the amount of addition of polyvinylpyrrolidone (PVP) was changed to 0.15 g and nitric acid was used instead of ammonia to adjust the pH of the polishing composition to 9.5. After removal of the natural oxide film by polishing was performed, polishing composition 5 was used to perform polishing of the object to be polished.

### Example 6

Polishing composition 6 was completed in the same manner as in Example 4 except that nitric acid was used instead of ammonia to adjust the pH of the polishing composition to 8.5. After removal of the natural oxide film by polishing was performed, polishing composition 6 was used to perform polishing of the object to be polished.

### Example 7

300 g of ultrapure water was added to 1.0 g of 1-(2-aminoethyl) piperazine (AEP) as the component (A) and the resultant was stirred. Next, 0.5 g of polyvinylpyrrolidone (PVP) as the component (B) was added, and ultrapure water was added so that the total mass of the polishing composition was 1 kg, thereby completing polishing composition 7. After removal of the natural oxide film by etching, polishing composition 7 was used to perform polishing of the object to be polished.

### Example 8

After removal of the natural oxide film by polishing was performed, polishing composition 7 described above was used to perform polishing of the object to be polished.

### Example 9

Polishing composition 8 was completed in the same manner as in Example 7 except that the amount of addition of polyvinylpyrrolidone (PVP) was changed to 0.1 g. After removal of the natural oxide film by polishing was performed, polishing composition 8 was used to perform polishing of the object to be polished.

### Example 10

Polishing composition 9 was completed in the same manner as in Example 9 except that the amount of addition of polyvinylpyrrolidone (PVP) was changed to 0.30 g. After removal of the natural oxide film by polishing was performed, polishing composition 9 was used to perform polishing of the object to be polished.

### Example 11

Polishing composition 10 was completed in the same manner as in Example 9 except that the amount of addition of 1-(2-aminoethyl) piperazine (AEP) was changed to 5.0 g and furthermore acetic acid was used to adjust the pH of the polishing composition to 10.5. After removal of the natural oxide film by polishing was performed, polishing composition 10 was used to perform polishing of the object to be polished.

### Example 12

Polishing composition 11 was completed in the same manner as in Example 7 except that the amount of addition of polyvinylpyrrolidone (PVP) was changed to 0.075 g. After removal of the natural oxide film by polishing was performed, polishing composition 11 was used to perform polishing of the object to be polished.

### Example 13

Polishing composition 12 was completed in the same manner as in Example 7 except that the amount of addition of polyvinylpyrrolidone (PVP) was changed to 0.025 g. After removal of the natural oxide film by polishing was performed, polishing composition 12 was used to perform polishing of the object to be polished.

### Example 14

300 g of ultrapure water was added to 1.0 g of 1-(2-aminoethyl) piperazine (AEP) as the component (A) and the resultant was stirred. Next, 0.1 g of polyvinylpyrrolidone (PVP) as the component (B), 2.0 g of ammonium acetate, and 300 g of ultrapure water were added. Furthermore, ammonia as the pH adjusting agent was added in an amount so that the final pH of the polishing composition was 10.5, and ultrapure water was added so that the total mass of the polishing composition was 1 kg, thereby completing polishing composition 13. After removal of the natural oxide film by polishing was performed, polishing composition 13 was used to perform polishing of the object to be polished.

### Example 15

Polishing composition 14 was completed in the same manner as in Example 11 except that nitric acid was used instead of acetic acid to adjust the pH of the polishing composition to 9.5. After removal of the natural oxide film by polishing was performed, polishing composition 14 was used to perform polishing of the object to be polished.

### Example 16

300 g of ultrapure water was added to 5.0 g of 1-(2-aminoethyl) piperazine (AEP) as the component (A) and the resultant was stirred. Next, 0.15 g of polyvinylpyrrolidone (PVP) as the component (B) and 300 g of ultrapure water were added. Furthermore, nitric acid as the pH adjusting agent was added in an amount so that the final pH of the polishing composition was 9.5, and ultrapure water was added so that the total mass of the polishing composition was 1 kg, thereby completing polishing composition 15. After removal of the natural oxide film by polishing was performed, polishing composition 15 was used to perform polishing of the object to be polished.

### Example 17

After removal of the natural oxide film by etching, polishing composition 15 described above was used to perform polishing of the object to be polished.

### Example 18

Polishing composition 16 was completed in the same manner as in Example 16 except that the amount of addition of polyvinylpyrrolidone (PVP) was changed to 0.3 g. After removal of the natural oxide film by polishing was performed, polishing composition 16 was used to perform polishing of the object to be polished.

### Example 19

Polishing composition 17 was completed in the same manner as in Example 16 except that the amount of addition of 1-(2-aminoethyl) piperazine (AEP) was changed to 1.0 g and the amount of addition of polyvinylpyrrolidone (PVP) was changed to 0.1 g. After removal of the natural oxide film by polishing was performed, polishing composition 17 was used to perform polishing of the object to be polished.

### Example 20

Polishing composition 18 was completed in the same manner as in Example 19 except that nitric acid was used to adjust the pH of the polishing composition to 9.0. After removal of the natural oxide film by polishing was performed, polishing composition 18 was used to perform polishing of the object to be polished.

### Example 21

Polishing composition 19 was completed in the same manner as in Example 16 except that the amount of addition of 1-(2-aminoethyl) piperazine (AEP) was changed to 1.0 g and the amount of addition of polyvinylpyrrolidone (PVP) was changed to 0.025 g. After removal of the natural oxide film by polishing was performed, polishing composition 19 was used to perform polishing of the object to be polished.

### Example 22

Polishing composition 20 was completed in the same manner as in Example 16 except that the amount of addition of 1-(2-aminoethyl) piperazine (AEP) was changed to 1.0 g, the amount of addition of polyvinylpyrrolidone (PVP) was changed to 0.5 g, and furthermore nitric acid was used to adjust the pH of the polishing composition to 8.5. After removal of the natural oxide film by polishing was performed, polishing composition 20 was used to perform polishing of the object to be polished.

### Example 23

Polishing composition 21 was completed in the same manner as in Example 16 except that the amount of addition of 1-(2-aminoethyl) piperazine (AEP) was changed to 1.0 g, the amount of addition of polyvinylpyrrolidone (PVP) was changed to 0.1 g, and furthermore nitric acid was used to adjust the pH of the polishing composition to 8.5. After removal of the natural oxide film by polishing was performed, polishing composition 21 was used to perform polishing of the object to be polished.

### Example 24

Polishing composition 22 was completed in the same manner as in Example 16 except that the amount of addition of polyvinylpyrrolidone (PVP) was changed to 0.1 g and furthermore nitric acid was used to adjust the pH of the polishing composition to 8.5. After removal of the natural oxide film by polishing was performed, polishing composition 22 was used to perform polishing of the object to be polished.

### Example 25

Polishing composition 23 was completed in the same manner as in Example 16 except that the amount of addition of 1-(2-aminoethyl) piperazine (AEP) was changed to 1.0 g, the amount of addition of polyvinylpyrrolidone (PVP) was changed to 0.075 g, and furthermore nitric acid was used to adjust the pH of the polishing composition to 8.5. After removal of the natural oxide film by polishing was performed, polishing composition 23 was used to perform polishing of the object to be polished.

### Example 26

Polishing composition 24 was completed in the same manner as in Example 16 except that the amount of addition of 1-(2-aminoethyl) piperazine (AEP) was changed to 1.0 g, the amount of addition of polyvinylpyrrolidone (PVP) was changed to 0.05 g, and furthermore nitric acid was used to adjust the pH of the polishing composition to 8.5. After removal of the natural oxide film by polishing was performed, polishing composition 24 was used to perform polishing of the object to be polished.

### Example 27

Polishing composition 25 was completed in the same manner as in Example 16 except that the amount of addition of 1-(2-aminoethyl) piperazine (AEP) was changed to 1.0 g, the amount of addition of polyvinylpyrrolidone (PVP) was changed to 0.025 g, and furthermore nitric acid was used to adjust the pH of the polishing composition to 8.5. After removal of the natural oxide film by polishing was performed, polishing composition 25 was used to perform polishing of the object to be polished.

### Example 28

Polishing composition 26 was completed in the same manner as in Example 27 except that polyvinyl alcohol (PVA) was used instead of polyvinylpyrrolidone (PVP). After removal of the natural oxide film by polishing was performed, polishing composition 26 was used to perform polishing of the object to be polished.

### Example 29

Polishing composition 27 was completed in the same manner as in Example 16 except that the amount of addition of 1-(2-aminoethyl) piperazine (AEP) was changed to 10.0 g. After removal of the natural oxide film by polishing was performed, polishing composition 27 was used to perform polishing of the object to be polished.

### Example 30

Polishing composition 28 was completed in the same manner as in Example 16 except that the amount of addition of 1-(2-aminoethyl) piperazine (AEP) was changed to 20.0 g. After removal of the natural oxide film by polishing was performed, polishing composition 28 was used to perform polishing of the object to be polished.

### Example 31

Polishing composition 29 was completed in the same manner as in Example 16 except that the amount of addition of 1-(2-aminoethyl) piperazine (AEP) was changed to 40.0 g. After removal of the natural oxide film by polishing was performed, polishing composition 29 was used to perform polishing of the object to be polished.

### Example 32

Polishing composition 30 was completed in the same manner as in Example 5 except that 1.0 g of 1,4-bis(3-aminopropyl) piperazine (BAPP) was used instead of 1,4-diazabicyclo[2.2.2]octane (DABCO). After removal of the natural oxide film by polishing was performed, polishing composition 30 was used to perform polishing of the object to be polished.

### Example 33

Polishing composition 31 was completed in the same manner as in Example 32 except that the amount of addition of 1,4-bis(3-aminopropyl) piperazine (BAPP) was changed to 5.0 g. After removal of the natural oxide film by polishing was performed, polishing composition 31 was used to perform polishing of the object to be polished.

### Comparative Example 1

Ammonia as the pH adjusting agent was added in an amount so that the final pH of the polishing composition was 10.5, and ultrapure water was added so that the total mass of the polishing composition was 1 kg, thereby completing polishing composition comparison 1. After removal of the natural oxide film by polishing was performed, polishing composition comparison 1 was used to perform polishing of the object to be polished.

### Comparative Example 2

300 g of ultrapure water was added to 1.0 g of 1-(2-aminoethyl) piperazine (AEP) and the resultant was stirred. Next, nitric acid as the pH adjusting agent was added in an amount so that the final pH of the polishing composition was 8.5, and ultrapure water was added so that the total mass of the polishing composition was 1 kg, thereby completing polishing composition comparison 2. After removal of the natural oxide film by polishing was performed, polishing composition comparison 2 was used to perform polishing of the object to be polished.

### Comparative Example 3

Polishing composition comparison 3 was completed in the same manner as in Comparative Example 2 except that the pH adjusting agent was changed to phosphoric acid and such phosphoric acid was added in an amount so that the final pH of the polishing composition was 7.5. After removal of the natural oxide film by polishing was performed, polishing composition comparison 3 was used to perform polishing of the object to be polished.

### Comparative Example 4

300 g of ultrapure water was added to 0.5 g of polyvinylpyrrolidone (PVP) as the component (B) and the resultant was stirred. Next, colloidal silica (average primary particle size: 35 nm, average secondary particle size: 70 nm) as the abrasive grain was added so that the final concentration was 1.9% by mass, and furthermore 300 g of ultrapure water was added. Next, ammonia as the pH adjusting agent was added in an amount so that the final pH of the polishing composition was 10.0, and ultrapure water was added so that the total mass of the polishing composition was 1 kg, thereby completing polishing composition comparison 4. Polishing composition comparison 4 was used to perform polishing of the object to be polished without removal of any natural oxide film by polishing.

### Comparative Example 5

300 g of ultrapure water was added to 1.0 g of 1-(2-aminoethyl) piperazine (AEP) as the component (A) and the resultant was stirred. Next, 0.025 g of polyvinylpyrrolidone (PVP) as the component (B) and 300 g of ultrapure water were added, and furthermore colloidal silica (average primary particle size: 35 nm, average secondary particle size: 70 nm) as the abrasive grain was added so that the final concentration was 1.9% by mass. Next, ultrapure water was added so that the total mass of the polishing composition was 1 kg, thereby completing polishing composition comparison 5. However, the abrasive grain in the polishing composition was aggregated during storage, and each evaluation could not be performed.

### [Polishing Conditions]

Each of the polishing compositions of Examples and Comparative Examples, obtained above, was used to polish the object to be polished in the following polishing conditions:
Polishing apparatus: F-REX 300SII manufactured by Ebara Corporation
Polishing pad: IK4250H (shore D hardness: 60) manufactured by Du Pont
Dresser: A188 manufactured by 3M
Polishing time: 20 seconds
Pressure of polishing table: 2.5 psi (17.2 kPa)
Number of rotations of polishing table: 60 rpm
Number of rotations of carrier: 63 rpm
Supply rate of polishing composition: 200 ml/min.

### [Dressing Conditions]

A dressing operation of the polishing pad was performed with pure water in the following conditions:
(the polishing apparatus, the polishing pad, and the dresser were the same as those in the above [Polishing conditions])
   Number of rotations of polishing table during dressing operation: 90 rpm
   Pushing force of dresser to polishing table (polishing pad): 22N
   Dressing operation time: Ex-situ 15 seconds
   Flow rate of pure water flowing during dressing operation: 2,000 ml/min.

### [Measurement of Polishing Removal Rate]

The polishing removal rate (polishing rate) of the object to be polished was calculated by the following expression.

$$[ Expression 1 ]$$

$$Polishing removal rate [ Å / min ] = ( Film thickness [ Å ] before polishing - Film thickness [ Å ] after polishing ) / Polishing time [ min ]$$

The film thicknesses before and after polishing of the object to be polished were determined with a light interference type film thickness measurement apparatus (Model number: A-SET F5X manufactured by KLA-Tencor), and the difference therebetween was divided by the polishing time to calculate the polishing removal rate.

### [Number of Defects]

A surface of the polished object for polishing removal rate evaluation (silicon wafer having an amorphous silicon film), obtained by the polishing, was evaluated about the number of defects (scratches and residues) of a size of 40 nm or more, according to the following method. Specifically, a defect detection apparatus (wafer inspection apparatus) “Surfscan SP5” manufactured by KLA-Tencor was used to measure the number of defects of 40 nm or more on the entire object to be polished (except for an area within 5 mm from the outer periphery). The number of defects measured was rated according to the following criteria. Rating A or B can allow for practical use:
A: 20,000 or less
B: more than 20,000 and 50,000 or less
C: more than 50,000 and 100,000 or less
D: more than 100,000.

### [Unevenness Elimination Ability (Unevenness Elimination Efficiency)]

The above-prepared object to be polished for unevenness elimination ability evaluation was cut to a 6-cm square and a surface thereof was polished by only a thickness of 1000 Å in the following polishing conditions. The value of the unevenness elimination efficiency was obtained as the value by dividing the amount of unevenness elimination (initial unevenness-unevenness after polishing), as determined by subtracting the unevenness after polishing from the initial unevenness, by the amount of polishing (1000 Å), as expressed in terms of percentage (see the following expression). Such unevenness was measured with an atomic force microscope (AFM, manufactured by Bruker, Dimention ICON). As the unevenness elimination efficiency, a numerical value closer to 100% is preferable:
Polishing apparatus: desktop polishing machine EJ-380 IN manufactured by ENGIS JAPAN Corporation
Polishing pad: IK4250H (shore D hardness: 60) manufactured by Du Pont
Pressure of polishing table: 2.5 psi (17.2 kPa)
Number of rotations of polishing table: 90 rpm
Supply rate of polishing composition: 20 ml/min.

$$[ Expression 2 ]$$

$$Unevenness elimination efficiency ( \% ) = ( Amount of unevenness elimination / Amount of polishing ) \times 100$$

The constitutions of the polishing compositions of Examples and Comparative Examples are shown in Table 1 below, and the results of each evaluation described above are shown in Table 2 below.

TABLE 1-1

| | | (A) Amine compound | | (B) Water-soluble | | | | | | | | |
|---|---|---|---|---|---|---|---|---|---|---|---|---|
| | | | Con- | polymer | | | Content | | Electrical | | | Electric |
| | Com- | | centration | | | Con- | mass | Abrasive | conductivity | pH | | con- |
| | position | | (% by | | | centration | ratio | grain (% | adjusting | adjusting | | ductivity |
| | No. | Type | mass) | Type | Mw | (% by mass) | (A)/(B) | by mass) | agent | agent | pH | (mS/cm) |
| Example | 1 | Imidazole | 0.1 | PVP | 45,000 | 0.01 | 10.0 | — | — | Ammonia | 10.5 | 0.3 |
| 1 | | | | | | | | | | | | |
| Example | 2 | Imidazole | 0.5 | PVP | 45,000 | 0.01 | 50.0 | — | — | Ammonia | 10.5 | 0.3 |
| 2 | | | | | | | | | | | | |
| Example | 3 | DABCO | 0.1 | PVP | 45,000 | 0.01 | 10.0 | — | — | Ammonia | 10.5 | 0.3 |
| 3 | | | | | | | | | | | | |
| Example | 4 | DABCO | 0.5 | PVP | 45,000 | 0.01 | 50.0 | — | — | Ammonia | 10.5 | 0.3 |
| 4 | | | | | | | | | | | | |
| Example | 5 | DABCO | 0.5 | PVP | 45,000 | 0.015 | 33.3 | — | — | Nitric | 9.5 | 0.87 |
| 5 | | | | | | | | | | acid | | |
| Example | 6 | DABCO | 0.5 | PVP | 45,000 | 0.01 | 50.0 | — | — | Nitric | 8.5 | 0.6 |
| 6 | | | | | | | | | | acid | | |
| Example | 7 | AEP | 0.1 | PVP | 45,000 | 0.05 | 2.0 | — | — | — | 10.5 | 0.1 |
| 7 | | | | | | | | | | | | |
| Example | 7 | ↑ | ↑ | ↑ | ↑ | ↑ | ↑ | ↑ | ↑ | ↑ | ↑ | ↑ |
| 8 | | | | | | | | | | | | |
| Example | 8 | AEP | 0.1 | PVP | 45,000 | 0.01 | 10.0 | — | — | — | 10.5 | 0.1 |
| 9 | | | | | | | | | | | | |
| Example | 9 | AEP | 0.1 | PVP | 45,000 | 0.03 | 3.3 | — | — | — | 10.5 | 0.1 |
| 10 | | | | | | | | | | | | |
| Example | 10 | AEP | 0.5 | PVP | 45,000 | 0.01 | 50.0 | — | — | Acetic | 10.5 | 0.2 |
| 11 | | | | | | | | | | acid | | |
| Example | 11 | AEP | 0.1 | PVP | 45,000 | 0.0075 | 13.3 | — | — | — | 10.5 | 0.1 |
| 12 | | | | | | | | | | | | |
| Example | 12 | AEP | 0.1 | PVP | 45,000 | 0.0025 | 40.0 | — | — | — | 10.5 | 0.1 |
| 13 | | | | | | | | | | | | |
| Example | 13 | AEP | 0.1 | PVP | 45,000 | 0.01 | 10.0 | — | Ammonium | Ammonia | 10.5 | 1.4 |
| 14 | | | | | | | | | acetate | | | |
| Example | 14 | AEP | 0.5 | PVP | 45,000 | 0.01 | 50.0 | — | — | Nitric | 9.5 | 2.3 |
| 15 | | | | | | | | | | acid | | |
| Example | 15 | AEP | 0.5 | PVP | 45,000 | 0.015 | 33.3 | — | — | Nitric | 9.5 | 2.3 |
| 16 | | | | | | | | | | acid | | |
| Example | 15 | ↑ | ↑ | ↑ | ↑ | ↑ | ↑ | ↑ | ↑ | ↑ | ↑ | ↑ |
| 17 | | | | | | | | | | | | |
| Example | 16 | AEP | 0.5 | PVP | 45,000 | 0.03 | 16.7 | — | — | Nitric | 9.5 | 2.3 |
| 18 | | | | | | | | | | acid | | |
| Example | 17 | AEP | 0.1 | PVP | 45,000 | 0.01 | 10.0 | — | — | Nitric | 9.5 | 0.5 |
| 19 | | | | | | | | | | acid | | |
| Example | 18 | AEP | 0.1 | PVP | 45,000 | 0.01 | 10.0 | — | — | Nitric | 9.0 | 0.9 |
| 20 | | | | | | | | | | acid | | |
| Example | 19 | AEP | 0.1 | PVP | 45,000 | 0.0025 | 40.0 | — | — | Nitric | 9.5 | 1.3 |
| 21 | | | | | | | | | | acid | | |
| Example | 20 | AEP | 0.1 | PVP\| | 45,000 | 0.05 | 2.0 | — | — | Nitric | 8.5 | 1.3 |
| 22 | | | | | | | | | | acid | | |
| Example | 21 | AEP | 0.1 | PVP | 45,000 | 0.01 | 10.0 | — | — | Nitric | 8.5 | 1.3 |
| 23 | | | | | | | | | | acid | | |
| Example | 22 | AEP | 0.5 | PVP | 45,000 | 0.01 | 50.0 | — | — | Nitric | 8.5 | 5.6 |
| 24 | | | | | | | | | | acid | | |
| Example | 23 | AEP | 0.1 | PVP\| | 45,000 | 0.0075 | 13.3 | — | — | Nitric | 8.5 | 1.3 |
| 25 | | | | | | | | | | acid | | |
| Example | 24 | AEP | 0.1 | PVP\| | 45,000 | 0.005 | 20.0 | — | — | Nitric | 8.5 | 1.3 |
| 26 | | | | | | | | | | acid | | |
| Example | 25 | AEP | 0.1 | PVP | 45,000 | 0.0025 | 40.0 | — | — | Nitric | 8.5 | 1.3 |
| 27 | | | | | | | | | | acid | | |
| Example | 26 | AEP | 0.1 | PVA | 10,000 | 0.0025 | 40.0 | — | — | Nitric | 8.5 | 1.3 |
| 28 | | | | | | | | | | acid | | |
| Example | 27 | AEP | 1.0 | PVP | 45,000 | 0.015 | 66.7 | — | — | Nitric | 9.5 | 4.4 |
| 29 | | | | | | | | | | acid | | |
| Example | 28 | AEP | 2.0 | PVP | 45,000 | 0.015 | 133.3 | — | — | Nitric | 9.5 | 8.4 |
| 30 | | | | | | | | | | acid | | |
| Example | 29 | AEP | 4.0 | PVP | 45,000 | 0.015 | 266.7 | — | — | Nitric | 9.5 | 13.9 |
| 31 | | | | | | | | | | acid | | |
| Example | 30 | BAPP | 0.1 | PVP | 45,000 | 0.015 | 6.7 | — | — | Nitric | 9.5 | 0.7 |
| 32 | | | | | | | | | | acid | | |
| Example | 31 | BAPP | 0.5 | PVP | 45,000 | 0.015 | 33.3 | — | — | Nitric | 9.5 | 3.1 |
| 33 | | | | | | | | | | acid | | |
| Com- | Com- | — | — | — | — | — | — | — | — | Ammonia | 10.5 | 0.1 |
| parative | parison | | | | | | | | | | | |
| Example | 1 | | | | | | | | | | | |
| 1 | | | | | | | | | | | | |
| Com- | Com- | AEP | 0.1 | — | — | — | — | — | — | Nitric | 8.5 | 1.3 |
| parative | parison | | | | | | | | | acid | | |
| Example | 2 | | | | | | | | | | | |
| 2 | | | | | | | | | | | | |
| Com- | Com- | AEP | 0.1 | — | — | — | — | — | — | Phosphoric | 7.5 | 1.1 |
| parative | parison | | | | | | | | | acid | | |
| Example | 3 | | | | | | | | | | | |
| 3 | | | | | | | | | | | | |
| Com- | Com- | — | — | PVP | 45,000 | 0.05 | 0 | 1.9 | — | Ammonia | 10.0 | 0.3 |
| parative | parison | | | | | | | | | | | |
| Example | 4 | | | | | | | | | | | |
| 4 | | | | | | | | | | | | |
| Com- | Com- | AEP | 0.1 | PVP | 45,000 | 0.0025 | 40.0 | 1.9 | — | — | 9.5 | 0.1 |
| parative | parison | | | | | | | | | | | |
| Example | 5 | | | | | | | | | | | |
| 5 | | | | | | | | | | | | |

TABLE 2

| | | Removal of | | | | Unevenness |
|---|---|---|---|---|---|---|
| | Composition | natural oxide | Polishing removal rate (Å/min) | | Number of | elimination |
| | No. | film | a-Si | SiN | defects | efficiency (%) |
| Example 1 | 1 | Polishing | 1977 | 0 | A | 21 |
| Example 2 | 2 | Polishing | 2064 | 0 | A | 21 |
| Example 3 | 3 | Polishing | 2199 | 0 | A | 22 |
| Example 4 | 4 | Polishing | 2474 | 0 | A | 22 |
| Example 5 | 5 | Polishing | 1721 | 0 | A | 30 |
| Example 6 | 6 | Polishing | 1591 | 0 | A | 38 |
| Example 7 | 7 | Etching | 1666 | 0 | A | 25 |
| Example 8 | 7 | Polishing | 1643 | 0 | A | 25 |
| Example 9 | 8 | Polishing | 2300 | 0 | A | 23 |
| Example 10 | 9 | Polishing | 1747 | 0 | A | 23 |
| Example 11 | 10 | Polishing | 2608 | 0 | A | 23 |
| Example 12 | 11 | Polishing | 3124 | 0 | B | 21 |
| Example 13 | 12 | Polishing | 3759 | 0 | B | 17 |
| Example 14 | 13 | Polishing | 2911 | 0 | A | 23 |
| Example 15 | 14 | Polishing | 2524 | 0 | A | 28 |
| Example 16 | 15 | Polishing | 2088 | 0 | A | 30 |
| Example 17 | 15 | Etching | 2097 | 0 | A | 30 |
| Example 18 | 16 | Polishing | 1803 | 0 | A | 30 |
| Example 19 | 17 | Polishing | 1979 | 0 | A | 30 |
| Example 20 | 18 | Polishing | 1664 | 0 | A | 34 |
| Example 21 | 19 | Polishing | 3675 | 0 | B | 18 |
| Example 22 | 20 | Polishing | 1015 | 0 | A | 42 |
| Example 23 | 21 | Polishing | 1431 | 0 | A | 40 |
| Example 24 | 22 | Polishing | 1723 | 0 | A | 40 |
| Example 25 | 23 | Polishing | 2194 | 0 | B | 35 |
| Example 26 | 24 | Polishing | 3005 | 0 | B | 25 |
| Example 27 | 25 | Polishing | 3045 | 0 | B | 20 |
| Example 28 | 26 | Polishing | 2652 | 0 | B | 17 |
| Example 29 | 27 | Polishing | 2261 | 0 | A | 26 |
| Example 30 | 28 | Polishing | 2469 | 0 | A | 25 |
| Example 31 | 29 | Polishing | 2712 | 0 | A | 24 |
| Example 32 | 30 | Polishing | 1683 | 0 | A | 30 |
| Example 33 | 31 | Polishing | 2048 | 0 | A | 30 |
| Comparative | Comparison 1 | Polishing | 724 | 0 | D | 14 |
| Example 1 | | | | | | |
| Comparative | Comparison 2 | Polishing | 2599 | 0 | D | 15 |
| Example 2 | | | | | | |
| Comparative | Comparison 3 | Polishing | 234 | 0 | D | — |
| Example 3 | | | | | | |
| Comparative | Comparison 4 | None | 2184 | 14.0 | C | — |
| Example 4 | | | | | | |
| Comparative | Comparison 5 | — | — | — | — | — |
| Example 5 | | | | | | |

As clear from Table 2 above, the polishing compositions of Examples were each found to be excellent in the balance among an excellent unevenness elimination ability on an object to be polished, an enhancement in polishing removal rate of an object to be polished, and a defect reduction on a surface of a polished object, as compared with the polishing compositions of Comparative Examples.

Herein, Comparative Example 3 exhibited a low polishing removal rate of a-Si, and thus evaluation of unevenness elimination ability was not performed. Comparative Example 4 exhibited a high polishing removal rate of SiN, and thus evaluation of unevenness elimination ability was not performed.

The present application is based on Japanese Patent Application No. 2025-044822 filed on Mar. 19, 2025 and Japanese Patent Application No. 2025-134337 filed on Aug. 12, 2025, the disclosures of which are herein incorporated by reference in their entireties.

1. A polishing composition comprising
(A) an amine compound having a heterocyclic structure containing two or more nitrogen atoms, and
(B) a water-soluble polymer,
wherein a content mass ratio of the component (A) to the component (B) (component (A)/component (B)) is 1 or more,
the polishing composition has a pH of 8 or more, and
the polishing composition is substantially free of an abrasive grain.

2. The polishing composition according to claim 1, wherein the (A) amine compound having a heterocyclic structure containing two or more nitrogen atoms comprises at least one selected from the group consisting of a compound having an imidazole ring structure, a compound having an aliphatic polycyclic structure, and a compound having a piperazine ring structure.

3. The polishing composition according to claim 1, wherein the (A) amine compound having a heterocyclic structure containing two or more nitrogen atoms comprises at least one selected from the group consisting of imidazole, 1,4-diazabicyclo[2.2.2]octane, and 1-(2-aminoethyl) piperazine.

4. The polishing composition according to claim 1, wherein the (B) water-soluble polymer comprises a non-ionic water-soluble polymer.

5. The polishing composition according to claim 4, wherein the non-ionic water-soluble polymer comprises polyvinylpyrrolidone.

6. The polishing composition according to claim 1, further comprising a dispersing medium.

7. The polishing composition according to claim 1, which is used for polishing of an object to be polished containing a material having a silicon-silicon bond.

8. The polishing composition according to claim 7, wherein the material having a silicon-silicon bond is amorphous silicon.

9. A method for producing a substrate, comprising
a step of removing a natural oxide film on a surface of an object to be polished containing a material having a silicon-silicon bond, and
a step of polishing the object to be polished containing a material having a silicon-silicon bond, with the polishing composition according to claim 1 and a polishing pad having a shore D hardness of 30 or more.

10. The method for producing a substrate according to claim 9, comprising performing the step of removing the natural oxide film, by polishing.

11. The method for producing a substrate according to claim 9, comprising performing the step of removing the natural oxide film, by etching.

12. A polishing system comprising an object to be polished containing a material having a silicon-silicon bond, a polishing pad having a shore D hardness of 30 or more, and a polishing composition,
wherein the polishing composition comprises
(A) an amine compound having a heterocyclic structure containing two or more nitrogen atoms, and
(B) a water-soluble polymer,
a content mass ratio of the component (A) to the component (B) (component (A)/component (B)) is 1 or more, the polishing composition has a pH of 8 or more, and the polishing composition is substantially free of an abrasive grain, and
wherein a surface of the object to be polished is contacted with the polishing pad and the polishing composition.
